(19) United States
(12) Patent Application Publication
(10) Pub. No.: US 2026/0026098 A1
(43) Pub. Date: Jan. 22, 2026

(54) SEMICONDUCTOR DEVICE

(71) Applicant: Samsung Electronics Co., Ltd., Suwon-si (KR)

(72) Inventors: Ju Hun PARK, Suwon-si (KR); Jae Hyun PARK, Suwon-si (KR); Jin Chan YUN, Suwon-si (KR); Jae Won JEONG, Suwon-si (KR); Kyu Man HWANG, Suwon-si (KR); Sang Woo HAN, Suwon-si (KR)

(21) Appl. No.: 19/223,162

(22) Filed: May 30, 2025

(30) Foreign Application Priority Data
Jul. 18, 2024 (KR) 10-2024-0095040

(51) Int. Cl. H10D 84/85; H10D 84/01

(52) U.S. Cl. CPC H10D 84/856; H10D 84/0186; H10D 84/851

(57) ABSTRACT

There is provided a semiconductor device that can improve device performance and reliability. The semiconductor includes a first channel pattern and a second channel pattern spaced apart in a first direction, a gate structure surrounding the first and second channel patterns, extending in a second direction, and including a gate insulating film and a gate electrode, and a backside gate contact penetrating the gate insulating film and including a contact surface that contacts the gate electrode, wherein the gate electrode has a first surface and a second surface opposite to each other in the first direction, the gate insulating film extends along the first surface of the gate electrode, and in a cross-sectional view in the second direction, the contact surface of the backside gate contact includes a first inclined flat surface and a second inclined flat surface that are inclined with respect to the first direction.

### CROSS-REFERENCE TO RELATED APPLICATION

This application claims priority from Korean Patent Application No. 10-2024-0095040 filed on Jul. 18, 2024 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a semiconductor device, and more particularly, to a semiconductor device including a Multi-Bridge Channel Field Effect Transistor (MBCFET™).

### 2. Description of the Related Art

As one of the scaling technologies to increase the density of semiconductor devices, multi-gate transistors have been proposed. The multi-gate transistors are obtained by forming multi-channel active patterns (or silicon bodies) in the shape of fins or nanowires on a substrate and then forming gates on the surfaces of the multi-channel active patterns.

The multi-gate transistors are easier to scale due to their utilization of three-dimensional (3D) channels. Additionally, the multi-gate transistors can improve current control capabilities without increasing their gate length. Moreover, the multi-gate transistors can effectively suppress the short channel effect (SCE), where the potential in a channel area is affected by the drain voltage.

Additionally, in order to implement more devices within the same area, semiconductor devices utilizing stacked multi-gate transistors, where the multi-gate transistors of an upper region are stacked on the multi-gate transistors of a lower region, are being researched.

### SUMMARY

Aspects of the present disclosure provide a semiconductor device that can improve device performance and reliability.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, a semiconductor device includes a first channel pattern and a second channel pattern spaced apart in a first direction, a gate structure surrounding the first channel pattern and the second channel pattern, the gate structure extending in a second direction and including a gate insulating film and a gate electrode, and a backside gate contact penetrating the gate insulating film and including a contact surface that contacts the gate electrode, wherein the gate electrode has a first surface and a second surface opposite to each other in the first direction, the gate insulating film extends along the first surface of the gate electrode, and in a cross-sectional view in the second direction, the contact surface of the backside gate contact includes a first inclined flat surface and a second inclined flat surface that are inclined with respect to the first direction.

According to an aspect of the present disclosure, a semiconductor device includes a first channel pattern and a second channel pattern spaced apart in a first direction, a gate structure surrounding the first channel pattern and the second channel pattern, the gate structure extending in a second direction and including a gate insulating film and a gate electrode, and a backside gate contact penetrating the gate insulating film and including a contact portion that contacts the gate electrode, wherein the gate electrode has a first surface and a second surface opposite to each other in the first direction, the gate insulating film extends along the first surface of the gate electrode, in a cross-sectional view in the second direction, the contact portion of the backside gate contact has a contact width in the second direction and a contact depth in the first direction, and a ratio of the contact depth to the contact width is between 0.25 and 1.

According to an aspect of the present disclosure, a semiconductor device includes a first lower channel pattern and a first upper channel pattern spaced apart from each other in a first direction, a first gate structure surrounding the first lower channel pattern and the first upper channel pattern, the first gate structure extending in a second direction, and including a first gate insulating film and a first gate electrode, wherein the first gate electrode has a first surface and a second surface opposite to each other in the first direction and the first gate insulating film extends along the first surface of the first gate electrode, a second lower channel pattern and a second upper channel pattern spaced apart from each other in the first direction, a second gate structure surrounding the second lower channel pattern and the second upper channel pattern, the second gate structure extending in the second direction and including a second gate insulating film and a second gate electrode, wherein the second gate electrode has a third surface and a fourth surface opposite to each other in the first direction and the second gate insulating film extends along the third surface of the second gate electrode, a backside gate contact penetrating the first gate insulating film and including a first contact surface that contacts the first gate electrode, and a frontside gate contact including a second contact surface that contacts the fourth surface of the second gate electrode, wherein in a cross-sectional view in the second direction, the first contact surface of the backside gate contact includes a first inclined flat surface and a second inclined flat surface that are inclined with respect to the first direction, and in a cross-sectional view in the second direction, the second contact surface of the frontside gate contact is a flat surface or a surface such that a middle portion of the second contact surface is at a lower vertical level than edge portions of the second contact surface.

It should be noted that the effects of the present disclosure are not limited to those described above, and other effects of the present disclosure will be apparent from the following description.

### BRIEF DESCRIPTION OF THE DRAWINGS

The above and other aspects and features of the present disclosure will become more apparent by describing in detail example embodiments thereof with reference to the attached drawings, in which:

FIG. 1 is an example layout view for explaining a semiconductor device according to some embodiments of the present disclosure.

FIG. 2 is an example cross-sectional view along line A-A in FIG. 1.

FIG. 3 is an example cross-sectional view along line B-B in FIG. 1.

FIG. 4 is an example cross-sectional view along line C-C in FIG. 1.

FIG. 5 is an example cross-sectional view along line D-D of FIG. 1.

FIG. 6 is an enlarged cross-sectional view of part P of FIG. 4.

FIGS. 7 and 8 are cross-sectional views for explaining a semiconductor device according to some embodiments.

FIGS. 9 and 10 are cross-sectional views for explaining a semiconductor device according to some embodiments.

FIGS. 11 and 12 are cross-sectional views for explaining a semiconductor device according to some embodiments.

FIGS. 13 to 15 are cross-sectional views for explaining a semiconductor device according to some embodiments.

FIGS. 16 to 18 are cross-sectional views for explaining a semiconductor device according to some embodiments.

FIGS. 19 to 21 are diagrams illustrating a semiconductor device according to some embodiments.

FIGS. 22 to 26 are diagrams illustrating a semiconductor device according to some embodiments.

FIGS. 27 to 30 are diagrams illustrating a semiconductor device according to some embodiments.

FIGS. 31 to 41 are diagrams illustrating steps of a method for manufacturing a semiconductor device according to some embodiments.

### DETAILED DESCRIPTION

It will be understood that, although the terms “first”, “second”, “third”, and so on may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

In the accompanying drawings related to semiconductor devices according to some embodiments of the present disclosure, various types of transistors are exemplified, including transistors containing nanowires or nanosheets or Multi-Bridge Channel Field Effect Transistors (MBCFETs™), but the present disclosure is not limited thereto.

The semiconductor devices according to some embodiments of the present disclosure may include Fin Field-Effect Transistors (FinFETs) with fin-shaped patterned channel areas, tunneling Field-Effect Transistors (FETs), three-dimensional (3D) transistors, or vertical FETs, and may also include planar transistors. Additionally, the technical concept of the present disclosure can be applied to transistors based on two-dimensional (2D) materials and their heterostructures. Furthermore, the semiconductor devices according to some embodiments of the present disclosure may also include bipolar junction transistors and Lateral Diffused Metal Oxide Semiconductor (LDMOS) transistors.

It will be understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Spatially relative terms, such as “beneath,” “below,” “lower,” “above,” “upper,” “top,” “bottom,” “on,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

An item, layer, or portion of an item or layer described as “extending” or as extending “lengthwise” in a particular direction has a length in the particular direction and a width perpendicular to that direction, where the length is greater than the width.

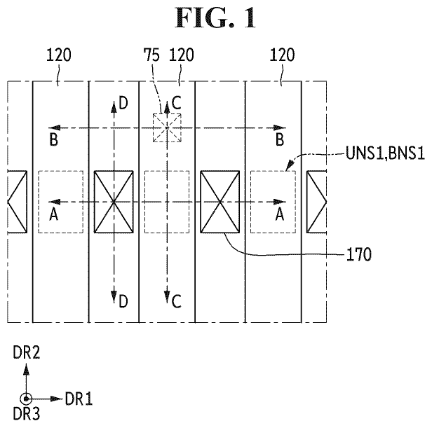

A semiconductor device according to some embodiments of the present disclosure will hereinafter be described with reference to FIGS. 1 to 6.

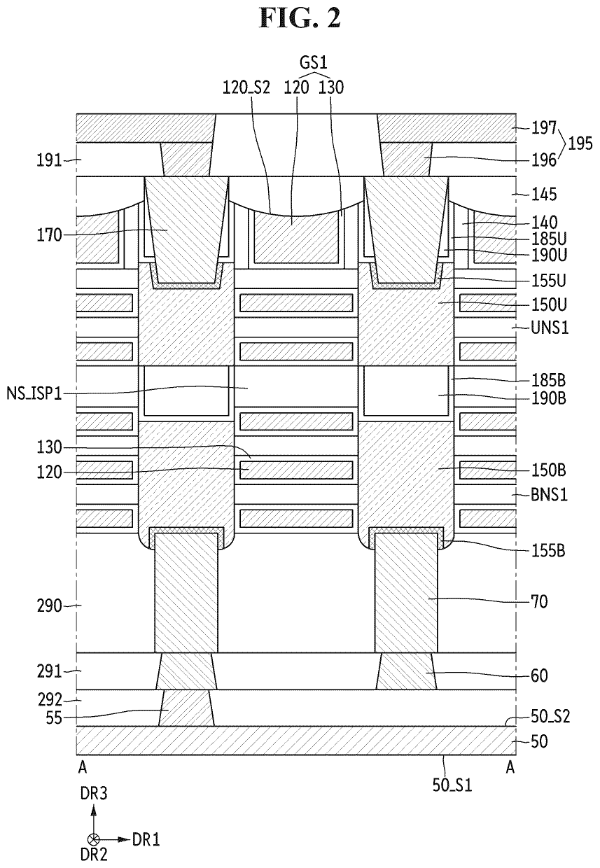

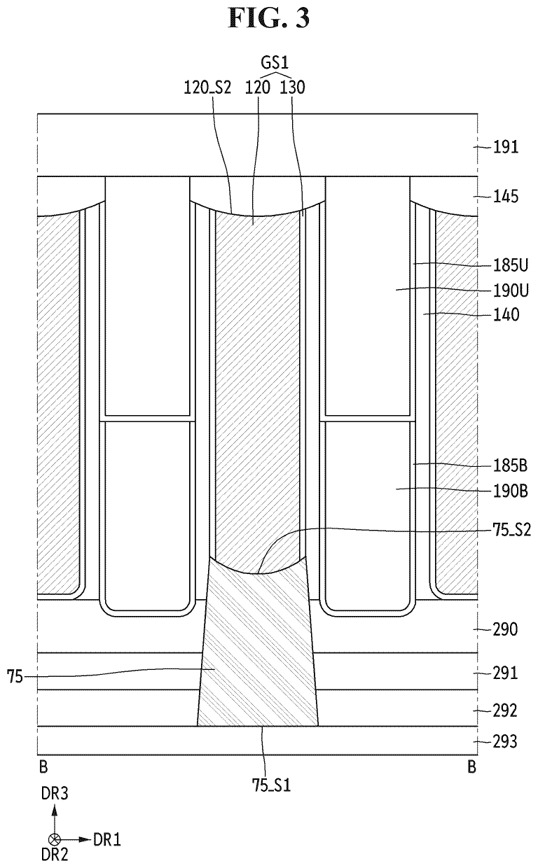

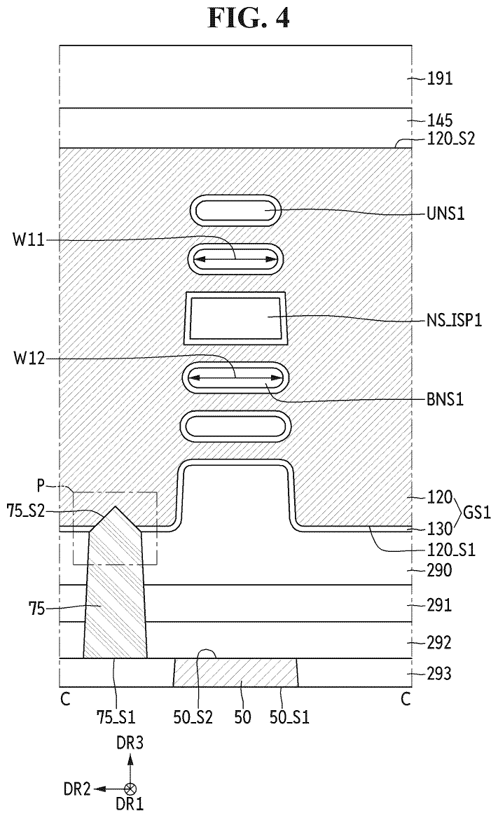

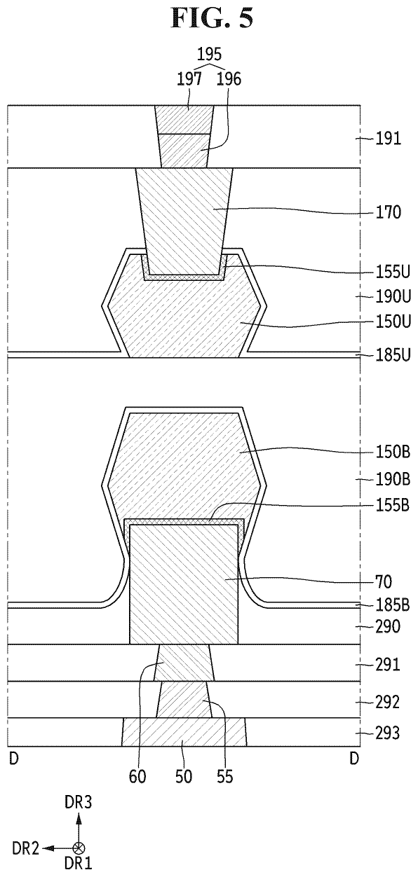

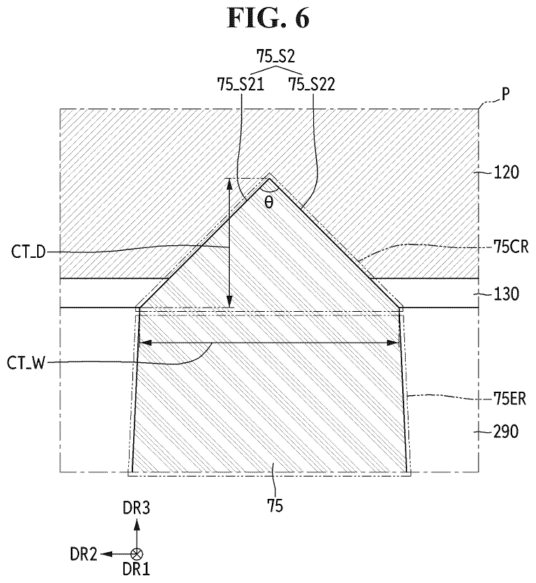

FIG. 1 is an example layout view for explaining a semiconductor device according to some embodiments of the present disclosure. FIG. 2 is an example cross-sectional view along line A-A in FIG. 1. FIG. 3 is an example cross-sectional view along line B-B in FIG. 1. FIG. 4 is an example cross-sectional view along line C-C in FIG. 1. FIG. 5 is an example cross-sectional view along line D-D of FIG. 1. FIG. 6 is an enlarged cross-sectional view of part P of FIG. 4.

Referring to FIGS. 1 to 6, the semiconductor device according to some embodiments may include first lower channel patterns BNS1, first upper channel patterns UNS1, first gate structures GS1, first lower source/drain patterns 150B, first upper source/drain patterns 150U, first intermediate insulating patterns NS_ISP1, first frontside source/drain contacts 170, first backside source/drain contacts 70, a first backside gate contact 75, and a backside wiring line 50.

A first backside interlayer insulating film 290 may have an upper surface and a bottom surface that are opposite to each other in a third direction DR3. The upper surface of the first backside interlayer insulating film 290 may have an uneven shape.

The first backside interlayer insulating film 290 may include at least one of, for example, silicon oxide, silicon nitride, silicon carbonitride, silicon oxynitride, and a low-dielectric material. The dielectric constant of the low-dielectric material may be less than the dielectric constant of silicon oxide, which is 3.9. The first backside interlayer insulating film 290 is illustrated as being a single film, but the present disclosure is not limited thereto.

One or more first lower channel patterns BNS1 may be disposed on the first backside interlayer insulating film 290. For example, the first lower channel patterns BNS1 may be disposed on the upper surface of the first backside interlayer insulating film 290.

The first lower channel patterns BNS1 may be spaced apart from the first backside interlayer insulating film 290 in the third direction DR3. When a plurality of first lower channel patterns BNS1 are disposed on the first backside interlayer insulating film 290, the first lower channel patterns BNS1 may be spaced apart from each other in the third direction DR3. Two first lower channel patterns BNS1 are illustrated as being disposed on the upper surface of the first backside interlayer insulating film 290, but the present disclosure is not limited thereto. Alternatively, one first lower channel pattern BNS1 or three or more first lower channel patterns BNS1 may be disposed on the upper surface of the first backside interlayer insulating film 290.

One or more first upper channel patterns UNS1 may be disposed on the upper surface of the first backside interlayer insulating film 290. The first upper channel patterns UNS1 may be disposed on the first lower channel patterns BNS1. The first lower channel patterns BNS1 may be disposed between the first backside interlayer insulating film 290 and the first upper channel patterns UNS1.

The first upper channel patterns UNS1 may be spaced apart from the first lower channel patterns BNS1 in the third direction DR3. When a plurality of first upper channel patterns UNS1 are disposed on the upper surface of the first backside interlayer insulating film 290, the first upper channel patterns UNS1 may be spaced apart from each other in the third direction DR3. Two first lower channel patterns BNS1 are illustrated as being disposed on the upper surface of the first backside interlayer insulating film 290, but the present disclosure is not limited thereto. Alternatively, one lower channel pattern BNS1 or three or more first lower channel patterns BNS1 may be disposed on the upper surface of the first backside interlayer insulating film 290. In addition, although the number of first upper channel patterns UNS1 is illustrated as being the same as the number of first lower channel patterns BNS1, this is merely for convenience of explanation and is not limited thereto.

The first lower channel patterns BNS1 may be connected to the first lower source/drain patterns 150B that will be described later. The first upper channel patterns UNS1 may be connected to the first upper source/drain patterns 150U. The first upper channel patterns UNS1 and the first lower channel patterns BNS1 may each have a nanosheet- or nanowire shape.

The first lower channel patterns BNS1 and the first upper channel patterns UNS1 may each include an elemental semiconductor material such as silicon (Si) or germanium (Ge). Additionally, the first lower channel patterns BNS1 and the first upper channel patterns UNS1 may each include a compound semiconductor, for example, a Group IV-IV compound semiconductor or a Group III-V compound semiconductor.

The Group IV-IV compound semiconductor may include, for example, a binary, ternary, or quaternary compound containing at least two of carbon (C), Si, Ge, and tin (Sn), or a compound obtained by doping this binary, ternary, or quaternary compound with a group IV element.

The Group III-V compound semiconductor may include, for example, a binary, ternary, or quaternary compound formed by combining at least one of aluminum (Al), gallium (Ga), and indium (In), which are Group III elements, with at least one of phosphorus (P), arsenic (As), and antimony (Sb), which are Group V elements.

As an example, the first lower channel patterns BNS1 may include the same material as the first upper channel patterns UNS1. In another example, the first lower channel patterns BNS1 may include a different material from the first upper channel patterns UNS1.

For example, in a cross-sectional view such as FIG. 4, a width W12 of the first lower channel patterns BNS1 in a second direction DR2 may be greater than a width W11 of the first upper channel pattern UNS1 in the second direction DR2. Alternatively, the width W12 of the first lower channel patterns BNS1 in the second direction DR2 may be the same as the width W11 of the first upper channel patterns UNS1 in the second direction DR2.

The first lower channel patterns BNS1 and the first upper channel patterns UNS1 may be included in transistors of different conductivity types. For example, the first lower channel patterns BNS1 may be used as the channel regions of P-type metal-oxide semiconductor (PMOS) transistors, and the first upper channel patterns UNS1 may be used as the channel regions of N-type metal-oxide semiconductor (NMOS) transistors. In another example, the first lower channel patterns BNS1 may be used as the channel regions of NMOS transistors, and the first upper channel patterns UNS1 may be used as the channel regions of PMOS transistors.

The first channel isolation patterns NS_ISP1 may be disposed between the first lower channel patterns BNS1 and the first upper channel patterns UNS1. The first channel isolation patterns NS_ISP1 may be spaced apart from the first lower channel patterns BNS1 in the third direction DR3. The first channel isolation patterns NS_ISP1 may be spaced apart from the first upper channel patterns UNS1 in the third direction DR3.

The first channel isolation patterns NS_ISP1 may include an insulating material. For example, the first channel isolation patterns NS_ISP1 may include at least one of silicon nitride, silicon oxycarbonitride, silicon boron carbonitride, silicon carbonitride, silicon oxide, silicon oxynitride, and a combination thereof.

A plurality of first gate structures GS1 may be disposed on the first backside interlayer insulating film 290. For example, the first gate structures GS1 may be disposed on the upper surface of the first backside interlayer insulating film 290.

The first gate structures GS1 may extend in the second direction DR2. The first gate structures GS1 may be spaced apart from each other in a first direction DR1. The first gate structures GS1 may be adjacent to each other in a first direction DR1. For example, the first direction DR1 may be orthogonal to the second and third directions DR2 and DR3. The second direction DR2 may be orthogonal to the third direction DR3.

The first gate structures GS1 may surround the first lower channel patterns BNS1 and the first upper channel patterns UNS1. For example, in a cross-sectional view cut in the second direction DR2, the first gate structures GS1 may surround the perimeters of the first lower channel pattern BNS1 and the perimeters of the first upper channel pattern UNS1. The first gate structures GS1 may surround the first channel isolation patterns NS_ISP1.

For example, the first gate structures GS1 may contact the first backside interlayer insulating film 290. The first gate structures GS1 may contact the upper surface of the first backside interlayer insulating film 290.

The first gate structures GS1 may include first gate electrodes 120 and a first gate insulating film 130.

The first gate electrodes 120 may be disposed on the first backside interlayer insulating film 290. The first gate electrodes 120 may extend in the second direction DR2.

The first gate electrodes 120 may surround the first lower channel patterns BNS1, the first upper channel patterns UNS1, and the first channel isolation patterns NS_ISP1. In other words, the first lower channel patterns BNS1, the first upper channel patterns UNS1, and the first channel isolation patterns NS_ISP1 may penetrate the first gate electrodes 120.

The first gate electrodes 120 may be disposed between each pair of adjacent first lower channel patterns BNS1 and between each pair of adjacent first upper channel patterns UNS1. The first gate electrodes 120 may be disposed between the first lower channel patterns BNS1 and the first backside interlayer insulating film 290, between the first lower channel patterns BNS1 and the first channel isolation patterns NS_ISP1, and between the first upper channel patterns UNS1 and the first channel isolation patterns NS_ISP1.

Parts of the first gate electrodes 120 surrounding the first lower channel patterns BNS1 and parts of the first gate electrodes 120 surrounding the first upper channel patterns UNS1 are illustrated as being single films, but the present disclosure is not limited thereto. Alternatively, the first gate electrodes 120 surrounding the first lower channel patterns BNS1 may be separated from the first gate electrode 120 surrounding the first upper channel pattern UNS1.

Each of the first gate electrodes 120 may have a first surface 120_S1 and a second surface 120_S2 that are opposite to each other in the third direction DR3. The first surface 120_S1 of the first gate electrodes 120 may face the first backside interlayer insulating film 290. The first surface 120_S1 of the first gate electrodes 120 may have an uneven shape.

In a cross-sectional view such as FIG. 2, the second surface 120_S2 of the first gate electrodes 120 is illustrated as being a concave surface (e.g., the second surface 120_S2 is curved or angled such that a middle portion in the first direction DR1 is at a lower vertical level than the edge portions in the first direction DR1), but the present disclosure is not limited thereto. Alternatively, the second surface 120_S2 of the first gate electrodes 120 may be flat.

The first gate electrodes 120 may include at least one of a metal, a metal alloy, a conductive metal nitride, a metal silicide, a doped semiconductor material, a conductive metal oxide, and a conductive metal oxynitride. The first gate electrodes 120 may include, for example, titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), Al, copper (Cu), cobalt (Co), titanium (Ti), tantalum (Ta), nickel (Ni), platinum (Pt), nickel platinum (NiPt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but the present disclosure is not limited thereto. Here, the conductive metal oxide and conductive metal oxynitride may include oxidized forms of the aforementioned materials, but the present disclosure is not limited thereto.

The first gate insulating film 130 may be disposed between the first gate electrodes 120 and the first backside interlayer insulating films 290. The first gate insulating film 130 may extend along the upper surface of the first backside interlayer insulating film 290. The first gate insulating film 130 may be in contact with the upper surface of the first backside interlayer insulating film 290.

The first gate insulating film 130 may be disposed on the first surface 120_S1 of the first gate electrodes 120. The first gate insulating film 130 may extend along the first surface 120_S1 of the first gate electrodes 120. The first gate insulating film 130 may be in contact with the first surface 120_S1 of the first gate electrodes 120. The first gate insulating film 130 may not extend along the second surface 120_S2 of the first gate electrodes 120.

The first gate insulating film 130 may be disposed between the first lower channel patterns BNS1 and the first gate electrodes 120, between the first upper channel patterns UNS1 and the first gate electrodes 120, and between the first channel isolation patterns NS_ISP1 and the first gate electrodes 120. The first gate insulating film 130 may be disposed along the perimeters of the first lower channel patterns BNS1, the perimeters of the first upper channel patterns UNS1, and the perimeters of the first channel isolation patterns NS_ISP1. The first gate electrodes 120 may be disposed on the first gate insulating film 130.

In the semiconductor device according to some embodiments, in a cross-sectional view such as FIG. 2, the first gate insulating film 130 may be in contact with the first lower source/drain patterns 150B and the first upper source/drain patterns 150U.

The first gate insulating film 130 may include at least one of silicon oxide, silicon oxynitride, silicon nitride, and a high-k dielectric material with a higher dielectric constant than silicon oxide. The high-k dielectric material may include, for example, at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. The first gate insulating film 130 is illustrated as being a single film, but the present disclosure is not limited thereto.

The semiconductor device according to some embodiments of the present disclosure may include a negative capacitance (NC) FET utilizing a negative capacitor. For example, the first gate insulating film 130 may include a ferroelectric material film with ferroelectric properties and a paraelectric material film with paraelectric properties.

The ferroelectric material film may have an NC, and the paraelectric material film may have positive capacitance. For example, if two or more capacitors are connected in series, and each of the capacitors has a positive capacitance, the total capacitance of the capacitors is reduced compared to the capacitance of each of the capacitors. Conversely, if at least one of the capacitors has an NC, the total capacitance of the capacitors may have a positive value and may be greater than the absolute value of the capacitance of each of the capacitors.

When a ferroelectric material film with an NC and a paraelectric material film with a positive capacitance are connected in series, the total capacitance of the ferroelectric and paraelectric material films may increase. Utilizing this capacitance increase, the transistor including the ferroelectric material film can have a subthreshold swing (SS) of 60 mV/decade or less at room temperature.

The ferroelectric material film may have ferroelectric properties. For example, the ferroelectric material film may include at least one of hafnium oxide, hafnium zirconium oxide, barium strontium titanium oxide, barium titanium oxide, and lead zirconium titanium oxide. Here, the hafnium zirconium oxide may be, for example, a material obtained by doping hafnium oxide with zirconium (Zr). Alternatively, the hafnium zirconium oxide may be the compound of hafnium (Hf), Zr, and oxygen (O).

The ferroelectric material film may further include a dopant. For example, the dopant may include at least one of Al, Ti, Nb, lanthanum (La), yttrium (Y), magnesium (Mg), Si, calcium (Ca), cerium (Ce), dysprosium (Dy), erbium (Er), gadolinium (Gd), Ge, scandium (Sc), strontium (Sr), and Sn. The type of the dopant included in the ferroelectric material film may vary depending on the type of the ferroelectric material included in the ferroelectric material film.

When the ferroelectric material film includes hafnium oxide, the dopant included in the ferroelectric material film may include at least one of Gd, Si, Zr, Al, and Y.

If the dopant is Al, the ferroelectric material film may contain 3 to 8 atomic % (at %) of Al. Here, the proportion of the dopant may be the ratio of Al to the sum of Hf and Al.

If the dopant is Si, the ferroelectric material film may contain 2 to 10 at % of Si. If the dopant is Y, the ferroelectric material film may contain 2 to 10 at % of Y. If the dopant is Gd, the ferroelectric material film may contain 1 to 7 at % of Gd. If the dopant is Zr, the ferroelectric material film may contain 50 to 80 at % of Zr.

The paraelectric material film may have paraelectric properties. For example, the paraelectric material film may include at least one of silicon oxide and a high-k metal oxide. The high-k metal oxide may include at least one of hafnium oxide, zirconium oxide, and aluminum oxide, but the present disclosure is not limited thereto.

The ferroelectric material film and the paraelectric material film may include the same material. The ferroelectric material film may have ferroelectric properties, but the paraelectric material film may not have ferroelectric properties. For example, if both the ferroelectric and paraelectric material films include hafnium oxide, the crystal structure of the hafnium oxide in the ferroelectric material film may differ from the crystal structure of the hafnium oxide in the paraelectric material film.

The ferroelectric material film may have a thickness that exhibits ferroelectric properties. For example, the thickness of the ferroelectric material film may be 0.5 to 10 nm, but the present disclosure is not limited thereto. Since the critical thickness for exhibiting ferroelectric properties may vary from one ferroelectric material to another, the thickness of the ferroelectric material film may vary depending on its material.

For example, the first gate insulating film 130 may include one ferroelectric material film. Alternatively, the first gate insulating film 130 may include a plurality of ferroelectric material films that are spaced apart from one another. The first gate insulating film 130 may have a layered film structure in which a plurality of ferroelectric material films and a plurality of paraelectric material films are alternately stacked.

The first gate spacers 140 may be disposed on the upper surface of the first backside interlayer insulating film 290. The first gate spacers 140 may be disposed on the sidewalls of the first gate electrodes 120. The first gate spacers 140 may not be disposed between the first backside interlayer insulating film 290 and the first lower channel patterns BNS1, nor between each pair of adjacent first lower channel patterns BNS1 in the third direction DR3. The first gate spacers 140 may not be disposed between the first channel isolation patterns NS_ISP1 and the first upper channel patterns UNS1, nor between each pair of adjacent first upper channel patterns UNS1 in the third direction DR3. The first gate spacers 140 may not be disposed between the first channel isolation patterns NS_ISP1 and the first lower channel patterns BNS1.

The first gate spacers 140 may include at least one of silicon nitride, silicon oxynitride, silicon oxide, silicon oxycarbonitride, silicon boron nitride, silicon boron oxynitride, silicon oxycarbide, and a combination thereof. The first gate spacers 140 are illustrated as being single films, but the present disclosure is not limited thereto.

The first gate capping patterns 145 may be disposed on the second surface 120_S2 of the first gate electrodes 120. The upper surface of the first gate capping patterns 145 may lie on the same plane as the upper surface of a first upper frontside interlayer insulating film 190U. Alternatively, the first gate capping patterns 145 may be disposed between the first gate spacers 140.

The first gate capping patterns 145 may include at least one of silicon nitride (SiN), silicon oxynitride (SiON), silicon carbonitride (SiCN), silicon oxycarbonitride (SiOCN), and a combination thereof. The first gate capping patterns 145 may include a material with an etch selectivity with respect to the first upper interlayer insulating film 190.

The first lower source/drain patterns 150B may be disposed on the first backside interlayer insulating film 290. The first lower source/drain patterns 150B may be disposed on at least one side of each of the first gate electrodes 120. For example, the first lower source/drain patterns 150B may be disposed on both sides of each of the first gate electrodes 120.

The first lower source/drain patterns 150B are connected to the first lower channel patterns BNS1. The first lower source/drain patterns 150B are in contact with the first lower channel patterns BNS1.

The first upper source/drain patterns 150U may be disposed on the first lower source/drain patterns 150B. The first upper source/drain patterns 150U may be spaced apart from the first lower source/drain patterns 150B in the third direction DR3.

The first upper source/drain patterns 150U may be disposed on at least one side of each of the first gate electrodes 120. For example, the first upper source/drain patterns 150U may be disposed on both sides of each of the first gate electrodes 120. The first upper source/drain patterns 150U are connected to the first upper channel patterns UNS1. The first upper source/drain patterns 150U are in contact with the first upper channel patterns UNS1.

The first lower source/drain patterns 150B may be included in the sources/drains of transistors using the first lower channel patterns BNS1 as channel regions. The first upper source/drain patterns 150U may be included in the sources/drains of transistors using the first upper channel patterns UNS1 as channel regions.

In FIG. 5, the first lower source/drain patterns 150B and the first upper source/drain patterns 150U are illustrated as having a hexagon shape, but the present disclosure is not limited thereto. Alternatively, the first lower source/drain patterns 150B and the first upper source/drain patterns 150U may have a pentagon, quadrilateral, or other polygon shape.

The first lower source/drain patterns 150B and the first upper source/drain patterns 150U may each include an epitaxial pattern. The first lower source/drain patterns 150B and the first upper source/drain patterns 150U may each include a semiconductor material.

For example, the first lower source/drain patterns 150B and the first upper source/drain patterns 150U may each include an elemental semiconductor material such as silicon or germanium. Additionally, the first lower source/drain patterns 150B and the first upper source/drain patterns 150U may each include, for example, a binary or ternary compound containing at least two elements selected from among C, Si, Ge, and Sn, or a compound obtained by doping the binary or ternary compound with a Group IV element. The first lower source/drain patterns 150B and the first upper source/drain patterns 150U may each include an epitaxial film formed of a semiconductor material. The first lower source/drain patterns 150B and the first upper source/drain patterns 150U are illustrated as being single films, but the present disclosure is not limited thereto.

In one example, the first lower source/drain patterns 150Bf may include a P-type dopant, and the first upper source/drain patterns 150U may include an N-type dopant. In another example, the first lower source/drain patterns 150B may include an N-type dopant, and the first upper source/drain patterns 150U may include a P-type dopant.

The P-type dopant may include at least one of boron (B) and Ga, but the present disclosure is not limited thereto. The N-type dopant may include at least one of P, As, Sb, and bismuth (Bi), but the present disclosure is limited thereto.

A first lower frontside interlayer insulating film 190B may be disposed on the upper surface of the first backside interlayer insulating film 290. The first lower frontside interlayer insulating film 190B may cover the first lower source/drain patterns 150B.

The first upper source/drain patterns 150U may be disposed on the first lower frontside interlayer insulating film 190B. The first lower frontside interlayer insulating film 190B may be disposed between the first lower source/drain patterns 150B and the first upper source/drain patterns 150U.

A lower source/drain etch stop film 185B may extend along the profile of the first lower source/drain patterns 150B. The lower source/drain etch stop film 185B may be disposed between the first backside interlayer insulating film 290 and the first lower frontside interlayer insulating film 190B. The lower source/drain etch stop film 185B may extend along the profile of the upper surface of the first backside interlayer insulating film 290.

Alternatively, contrary to what is illustrated, the lower source/drain etch stop film 185B may not be disposed between the first lower source/drain patterns 150B and the first lower frontside interlayer insulating film 190B.

The first upper frontside interlayer insulating film 190U may be disposed on the first lower frontside interlayer insulating film 190B. The first upper frontside interlayer insulating film 190U may cover the first upper source/drain patterns 150U.

An upper source/drain etch stop film 185U may be disposed between the first upper frontside interlayer insulating film 190U and the first upper source/drain patterns 150U. The upper source/drain etch stop film 185U may extend along at least part of the profile of the first upper source/drain patterns 150U.

Alternatively, in a cross-sectional view such as FIGS. 3 and 5, the first upper frontside interlayer insulating film 190U and the first lower frontside interlayer insulating film 190B may not be separated by the upper source/drain etch stop film 185U.

The first lower frontside interlayer insulating film 190B and the first upper frontside interlayer insulating film 190U may each include at least one of silicon oxide, silicon nitride, silicon oxynitride, and a low-k dielectric material. The lower source/drain etch stop film 185B and the upper source/drain etch stop film 185U may each include at least one of silicon nitride, silicon oxynitride, silicon oxycarbonitride, silicon boron nitride, silicon boron oxynitride, silicon carbonitride, silicon oxycarbide, and a combination thereof.

The first frontside source/drain contacts 170 may extend in the third direction DR3. The first frontside source/drain contacts 170 may be connected to the first upper source/drain patterns 150U. For example, the first frontside source/drain contacts 170 may be electrically connected to the first upper source/drain patterns 150U.

The first frontside source/drain contacts 170 are disposed on the upper surface of the first backside interlayer insulating film 290. The first frontside source/drain contacts 170 may be disposed within the first upper frontside interlayer insulating film 190U and the first upper source/drain patterns 150U. Parts of the first frontside source/drain contacts 170 may be disposed within the first upper source/drain patterns 150U. For example, the first frontside source/drain contact 170 may protrude into a portion of the first upper source/drain pattern 150U.

A first upper contact silicide film 155U may be disposed between the first frontside source/drain contacts 170 and the first upper source/drain patterns 150U. The first upper contact silicide film 155U may be in contact with the first frontside source/drain contacts 170.

The first frontside source/drain contacts 170 are illustrated as having a single conductive film structure, but the present disclosure is not limited thereto. Alternatively, the first frontside source/drain contacts 170 may have a multi-conductive film structure including a frontside contact barrier film and a frontside contact filling film.

The first frontside source/drain contacts 170 may include at least one of a metal, a conductive metal nitride, a conductive metal carbide, a conductive metal oxide, a conductive metal carbonitride, and a 2D material. The first upper contact silicide film 155U may include a metal silicide material.

A second frontside interlayer insulating film 191 may be disposed on the first upper frontside interlayer insulating film 190U, the first gate structures GS1, and the first frontside source/drain contacts 170. The second frontside interlayer insulating film 191 may include at least one of silicon oxide, silicon nitride, silicon carbonitride, silicon oxynitride, and a low-k dielectric material.

A frontside wiring structure 195 may be disposed within the second frontside interlayer insulating film 191. The frontside wiring structure 195 is disposed on a second surface 50_S2 of the backside wiring line 50, which will be described later. The frontside wiring structure 195 may include frontside via plugs 196 and a frontside wiring line 197.

The frontside wiring structure 195 may be connected to the first frontside source/drain contacts 170. The first frontside source/drain contacts 170 may be disposed between the frontside wiring structure 195 and the first upper source/drain patterns 150U in the third direction DR3 (see, e.g., FIG. 2). The first frontside source/drain contacts 170 may connect the frontside wiring structure 195 and the first upper source/drain patterns 150U. The first frontside source/drain contacts 170 may be connected to the frontside wiring line 197.

The frontside via plugs 196 and the frontside wiring line 197 may each include at least one of a metal, a conductive metal nitride, a conductive metal carbide, a conductive metal oxide, a conductive metal carbonitride, and a 2D material.

The frontside via plugs 196 and the frontside wiring line 197 are illustrated as having a single conductive film structure, but the present disclosure is not limited thereto. Alternatively, for example, the frontside via plugs 196 and/or the frontside wiring line 197 may have a multi-conductive film structure including a barrier film and a filling film. Alternatively, the frontside wiring structure 195 may have an integral structure with no distinct boundary between the frontside via plugs 196 and the frontside wiring line 197.

The first backside source/drain contacts 70 may extend in the third direction DR3. The first backside source/drain contacts 70 may be connected to the first lower source/drain patterns 150B. For example, the first backside source/drain contacts 70 may be electrically connected to the first lower source/drain patterns 150B.

The first backside source/drain contacts 70 may be disposed between the first lower source/drain patterns 150B and the backside wiring line 50. The first backside source/drain contacts 70 may overlap with the first lower source/drain patterns 150B in the third direction DR3.

The first backside source/drain contacts 70 connect the first lower source/drain patterns 150B to the backside wiring line 50. The first backside source/drain contacts 70 may be connected to the backside wiring line 50.

The first backside source/drain contacts 70 may be disposed within the first backside interlayer insulating film 290 and the first lower source/drain patterns 150B. Parts of the first backside source/drain contacts 70 may be disposed within the first lower source/drain patterns 150B. For example, the first backside source/drain contact 70 may protrude into a portion of the first lower source/drain pattern 150B.

A first lower contact silicide film 155B may be disposed between the first backside source/drain contacts 70 and the first lower source/drain patterns 150B. The first lower contact silicide film 155B may be in contact with the first backside source/drain contacts 70.

The first backside source/drain contacts 70 are illustrated as having a single conductive film structure, but the present disclosure is not limited thereto. Alternatively, contrary to what is illustrated, the first backside source/drain contacts 70 may have a multi-conductive film structure.

The first backside source/drain contacts 70 may include at least one of a metal, a conductive metal nitride, a conductive metal carbide, a conductive metal oxide, a conductive metal carbonitride, and a 2D material. The first lower contact silicide film 155B may include a metal silicide material.

A second backside interlayer insulating film 291, a third backside interlayer insulating film 292, and a fourth backside interlayer insulating film 293 may be disposed on the first backside interlayer insulating film 290. The second, third, and fourth backside interlayer insulating films 291, 292, and 293 may be sequentially disposed on the bottom surface of the first backside interlayer insulating film 290 (see, e.g., FIGS. 3-5).

The second, third, and fourth backside interlayer insulating films 291, 292, and 293 may each include at least one of silicon oxide, silicon nitride, silicon carbonitride, silicon oxynitride, and a low-k dielectric material. The second, third, and fourth backside interlayer insulating films 291, 292, and 293 are illustrated as being single films, but the present disclosure is not limited thereto.

Backside connection contacts 60 may be disposed within the second backside interlayer insulating film 291 (see, e.g., FIG. 5). The backside connection contacts 60 may be connected to the first backside source/drain contacts 70. The first backside source/drain contacts 70 may be disposed between the backside connection contacts 60 and the first lower source/drain patterns 150B. The backside connection contacts 60 may be electrically connected to the first lower source/drain patterns 150B.

A backside connection via 55 may be disposed within the third backside interlayer insulating film 292. The backside connection via 55 may be connected to a corresponding one of the backside connection contacts 60. The backside connection contacts 60 may be disposed between the backside connection via 55 and the first backside source/drain contacts 70. The backside connection via 55 may be electrically connected to the first lower source/drain patterns 150B.

The backside connection via 55 and the backside connection contacts 60 are illustrated as having a single conductive film structure, but the present disclosure is not limited thereto. Alternatively, contrary to what is illustrated, the backside connection via 55 and/or the backside connection contacts 60 may have a multi-conductive film structure.

The backside connection via 55 and the backside connection contacts 60 may each include at least one of a metal, a conductive metal nitride, a conductive metal carbide, a conductive metal oxide, a conductive metal carbonitride, and a 2D material.

The backside wiring line 50 may be disposed within the fourth backside interlayer insulating film 293. For example, the backside wiring line 50 may extend in the first direction DR1.

In one example, the backside wiring line 50 may be a power line that supplies power to the semiconductor device according to some embodiments. In another example, the backside wiring line 50 may be a signal line that supplies operational signals to the semiconductor device according to some embodiments.

The backside wiring line 50 may have a first surface 50_S1 and a second surface 50_S2 that are opposite to each other in the third direction DR3. The second surface 50_S2 of the backside wiring line 50 may face the first lower channel patterns BNS1, the first upper channel patterns UNS1, and the first gate electrodes 120. The first backside source/drain contacts 70 may be connected to the second surface 50_S2 of the backside wiring line 50.

The backside wiring line 50 is illustrated as having a single conductive film structure, but the present disclosure is not limited thereto. Alternatively, contrary to what is illustrated, the backside wiring line 50 may have a multi-conductive film structure including a wiring barrier film and a wiring filling film. In this case, the wiring filling film may fill the wiring filling film trench defined by the wiring barrier film.

The backside wiring line 50 may include at least one of a metal, a conductive metal nitride, a conductive metal carbide, a conductive metal oxide, a conductive metal carbonitride, and a 2D material. The 2D material may include a 2D allotrope or a 2D compound, for example, at least one of graphene, boron nitride (BN), molybdenum disulfide, molybdenum selenide, tungsten disulfide, tungsten selenide, and tantalum disulfide, but the present disclosure is not limited thereto. That is, these 2D materials listed herein are merely example, and the present disclosure is not limited thereto.

Alternatively, contrary to what is illustrated, the backside wiring line 50 may extend in the second direction DR2. In this case, the cross-sectional shapes of the backside wiring line 50 along lines A-A, B-B, C-C, and D-D of FIG. 1 may vary.

Alternatively, the backside wiring line 50 may include a line portion and a via portion. The line portion of the backside wiring line 50 may extend in the first direction DR1. The via portion of the backside wiring line 50 may protrude from the line portion of the backside wiring line 50 in the third direction DR3. The via portion of the backside wiring line 50 may protrude toward the first backside source/drain contacts 70.

Alternatively, the backside connection contacts 60 and/or the backside connection via 55 may not be disposed between the first backside source/drain contacts 70 and the backside wiring line 50.

The first backside gate contact 75 may extend in the third direction DR3. The first backside gate contact 75 may penetrate the first gate insulating film 130 on the first surface 120_S1 of the first gate electrode 120. The first backside gate contact 75 may be connected to the first gate electrodes 120. The first backside gate contact 75 may be in contact with the first gate electrodes 120.

The first backside gate contact 75 may be disposed within the first, second, and third backside interlayer insulating films 290, 291, and 292. Although not illustrated, the first backside gate contact 75 may be connected to the backside wiring line 50.

In the semiconductor device according to some embodiments, the first backside gate contact 75 may be connected to a first gate electrode 120 in a field region. In other words, the first backside gate contact 75 may not overlap with the first lower channel patterns BNS1 and the first upper channel patterns UNS1 in the third direction DR3.

The first backside gate contact 75 may have a first surface 75_S1 and a second surface 75_S2 that are opposite to each other in the third direction DR3. The second surface 75_S2 of the first backside gate contact 75 may face the first gate electrodes 120.

The second surface 75_S2 of the first backside gate contact 75 may be in contact with the first gate electrode 120. The second surface 75_S2 of the first backside gate contact 75 may be the contact surface of the first backside gate contact 75 that contacts the first gate electrode 120. The second surface 75_S2 of the first backside gate contact 75 may form at least part of the boundary between the first gate electrode 120 and the first backside gate contact 75.

In a cross-sectional view cut in the second direction DR2 (see, e.g., FIGS. 4 and 6), the second surface 75_S2 of the first backside gate contact 75 may have a convex shape. For example, the second surface 75_S2 is curved or angled such that a middle portion in the second direction DR2 is at a higher vertical level than the edge portions in the second direction DR2. As used herein, the term “higher vertical level” may be defined such that the first upper channel patterns UNS1 are at a higher vertical level than the first lower channel patterns BNS1. In FIGS. 4 and 6, the second surface 75_S2 of the first backside gate contact 75 may include a first inclined flat surface 75_S21 and a second inclined flat surface 75_S22. The first and second inclined flat surfaces 75_S21 and 75_S22 may each be inclined at any angle with respect to the third direction DR3. From a cross-sectional perspective, the first and second inclined flat surfaces 75_S21 and 75_S22 may have a rectilinear shape (see, e.g., FIG. 6).

In the semiconductor device according to some embodiments, the first and second inclined flat surfaces 75_S21 and 75_S22 may be directly connected. For example, an angle θ between the first and second inclined flat surfaces 75_S21 and 75_S22 may be 60 degrees or more and 120 degrees or less.

In the semiconductor device according to some embodiments, in a cross-sectional view cut in the first direction DR1 (see, e.g., FIG. 3), the second surface 75_S2 of the first backside gate contact 75 may have a concave shape (e.g., the second surface 75_S2 is curved or angled such that a middle portion in the first direction DR1 is at a lower vertical level than the edge portions in the first direction DR1).

The first backside gate contact 75 may include an extension portion 75ER and a contact portion 75CR (see, e.g., FIG. 6). The contact portion 75CR of the first backside gate contact 75 may be part of the first backside gate contact 75 that contacts the first gate electrode 120. For example, the contact portion 75CR of the first backside gate contact 75 may be in contact with the first gate electrode 120 and the first gate insulating film 130.

The contact portion 75CR of the first backside gate contact 75 may include the second surface 75_S2 of the first backside gate contact 75. The extension portion 75ER of the first backside gate contact 75 may include the first surface 75_S1 of the first backside gate contact 75.

In FIGS. 4 and 6, the contact portion 75CR of the first backside gate contact 75 may have a contact width CT_W in the second direction DR2 and a contact depth CT_D in the third direction DR3. The contact width CT_W may be the width of the part of the first backside gate contact 75 that is surrounded by the first gate electrode 120 and/or the first gate insulating film 130. The contact depth CT_D may be the depth of the part of the first backside gate contact 75 that is surrounded by the first gate electrode 120 and/or the first gate insulating film 130.

The contact width CT_W may be greater than or equal to the contact depth CT_D. For example, the ratio of the contact depth CT_D to the contact width CT_W may be 0.25 or more and 1 or less.

As the first backside gate contact 75 is inserted to a sufficient depth into the first gate electrode 120, the contact area between the first backside gate contact 75 and the first gate electrode 120 may increase. The contact area between the first backside gate contact 75 and the first gate electrode 120 is further increased by the presence of the first and second inclined flat surfaces 75_S21 and 75_S22. The increased contact area between the first backside gate contact 75 and the first gate electrode 120 may reduce the contact resistance between the first backside gate contact 75 and the first gate electrode 120. Accordingly, the performance and reliability of the semiconductor device according to some embodiments can be enhanced.

The first backside gate contact 75 is illustrated as having a single conductive film structure, but the present disclosure is not limited thereto. Alternatively, contrary to what is illustrated, the first backside gate contact 75 may have a multi-conductive film structure.

The first backside gate contact 75 may include at least one of a metal, a conductive metal nitride, a conductive metal carbide, a conductive metal oxide, a conductive metal carbonitride, and a 2D material.

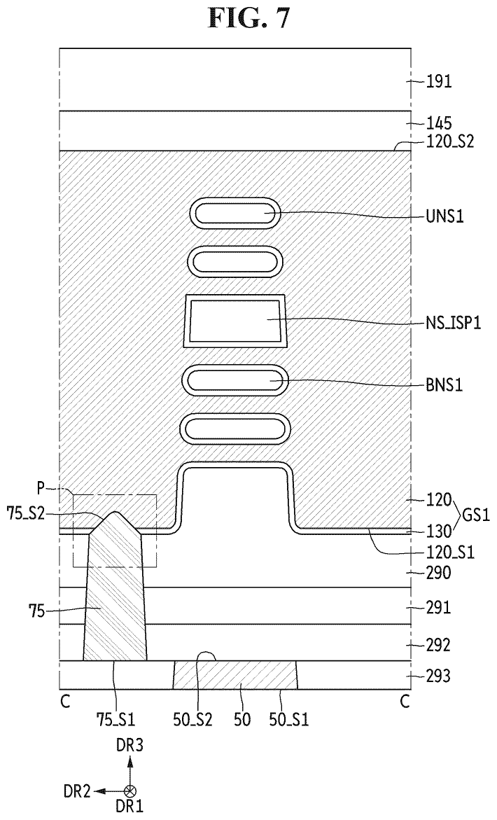

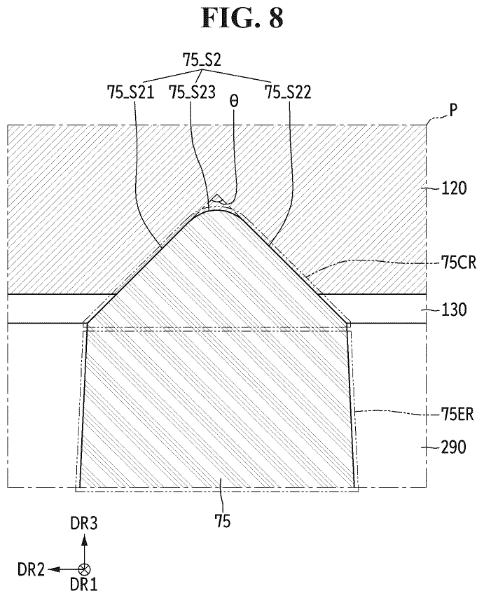

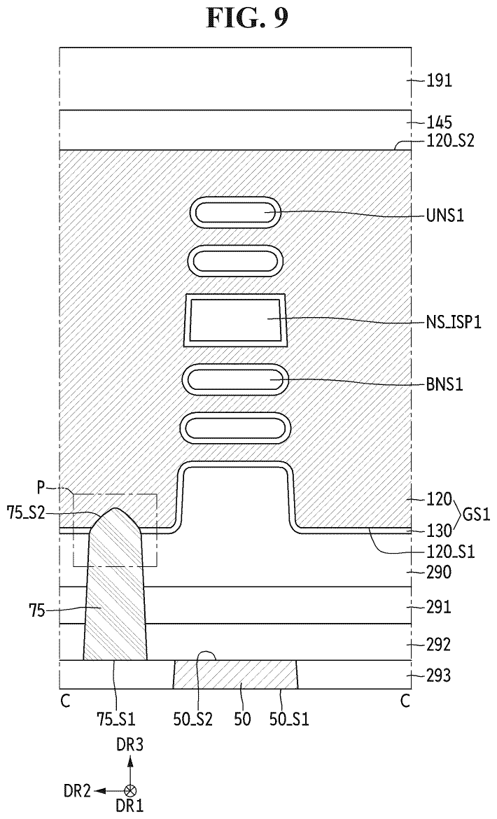

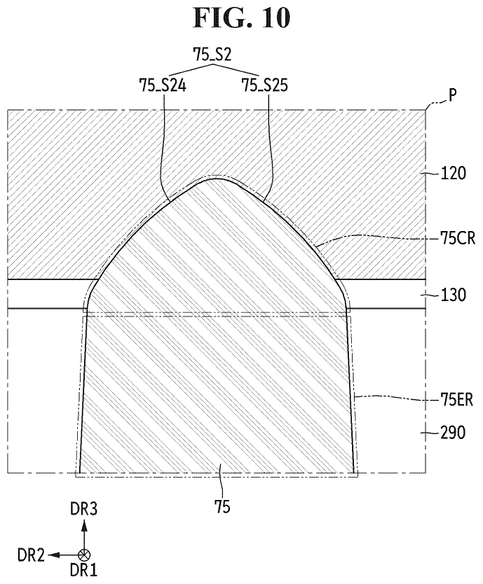

FIGS. 7 and 8 are cross-sectional views for explaining a semiconductor device according to some embodiments. FIGS. 9 and 10 are cross-sectional views for explaining a semiconductor device according to some embodiments. For convenience of explanation, the embodiments of FIGS. 7 to 10 will hereinafter be described, focusing on the differences from what has been described above with reference to FIGS. 1 to 6.

For reference, FIGS. 8 and 10 are enlarged cross-sectional views of part P of FIGS. 7 and 9, respectively.

Referring to FIGS. 7 and 8, in the semiconductor device according to some embodiments, a second surface 75_S2 of a first backside gate contact 75 may further include a contact connecting surface 75_S23.

The contact connecting surface 75_S23 may connect a first inclined flat surface 75_S21 to a second inclined flat surface 75_S22. The contact connecting surface 75_S23 may have, for example, a convex shape. For example, the contact connecting surface 75_S23 may be curved such that a middle portion in the second direction DR2 is at a higher vertical level than the edge portions in the second direction DR2. For example, the contact portion 75CR of the first backside gate contact 75 may have a rounded tip at an upper end thereof.

Referring to FIGS. 9 and 10, in the semiconductor device according to some embodiments, a second surface 75_S2 of a first backside gate contact 75 may include a first inclined curved surface 75_S24 and a second inclined curved surface 75_S25.

For example, the first and second inclined curved surfaces 75_S24 and 75_S25 may be directly connected to each other. For example, a first side of the second surface 75_S2 of the first backside gate contact 75 may be rounded or curved and a second side of the second surface 75_S2 of the first backside gate contact 75 may be rounded or curved. For example, the first side and the second side of the second surface 75_S2 of the first backside gate contact 75 may curve toward each other and may be directly connected to each other at upper ends or edges thereof.

Alternatively, contrary to what is illustrated, in a cross-sectional view cut in a second direction DR2, the second surface 75_S2 of the first backside gate contact 75 may have a shape in which inclined flat surfaces 75_S21 and 75_S22 and inclined curved surfaces 75_S24 and 75_S25 are connected.

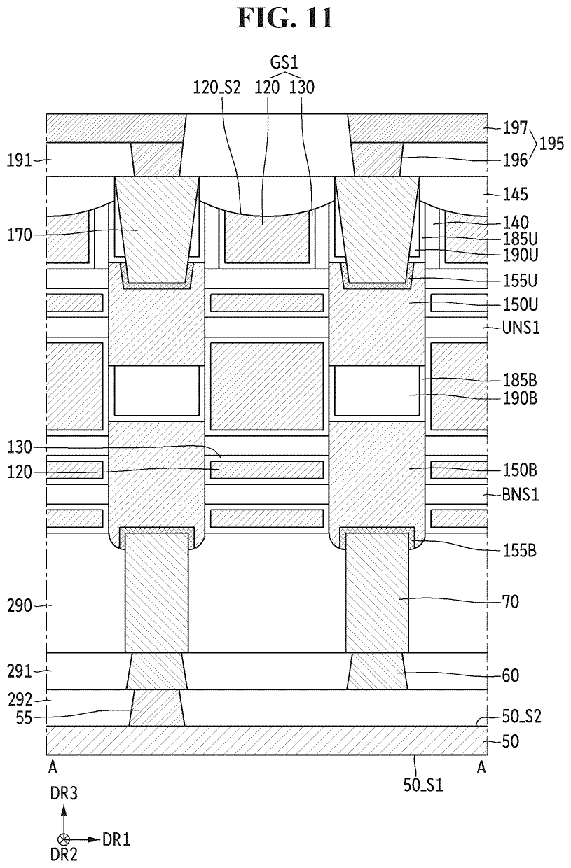

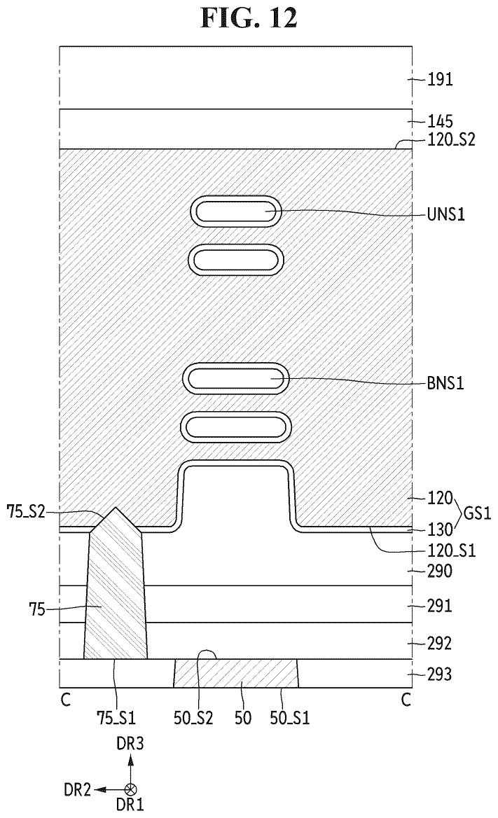

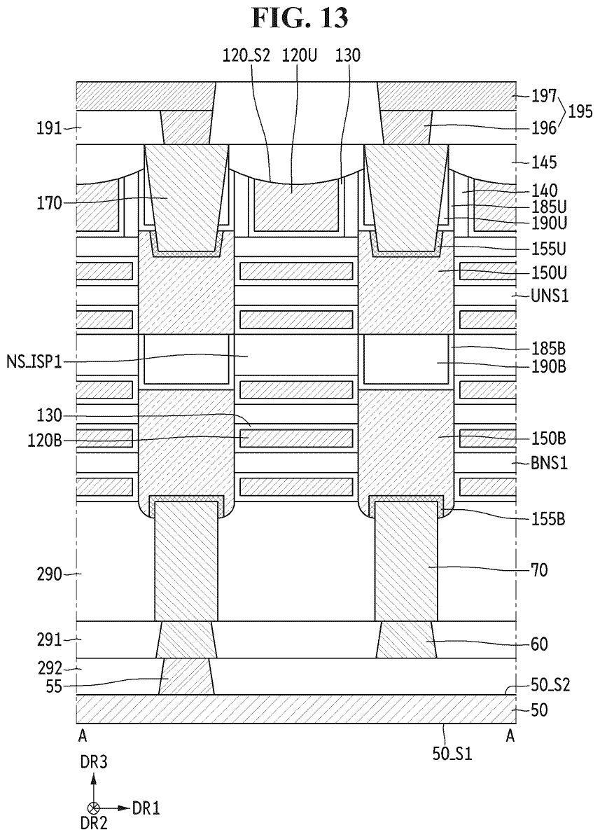

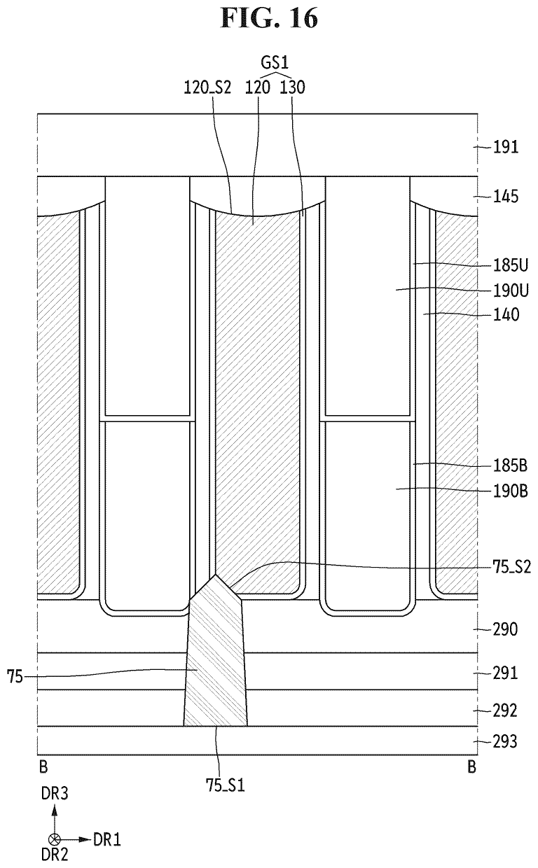

FIGS. 11 and 12 are cross-sectional views for explaining a semiconductor device according to some embodiments. FIGS. 13 to 15 are cross-sectional views for explaining a semiconductor device according to some embodiments. FIGS. 16 to 18 are cross-sectional views for explaining a semiconductor device according to some embodiments. For convenience of explanation, the embodiments of FIGS. 11 to 18 will hereinafter be described, focusing on the differences from what has been described above with reference to FIGS. 1 to 6.

Referring to FIGS. 11 and 12, in the semiconductor device according to some embodiments, first channel isolation patterns (“NS_ISP1” in FIGS. 2 and 4) are not disposed between first lower channel patterns BNS1 and first upper channel patterns UNS1.

The space between the first lower channel patterns BNS1 and the first upper channel patterns UNS1 may be filled by first gate structures GS1.

Referring to FIGS. 13 to 15, the semiconductor devices according to some embodiments may each further include a first frontside gate contact 175.

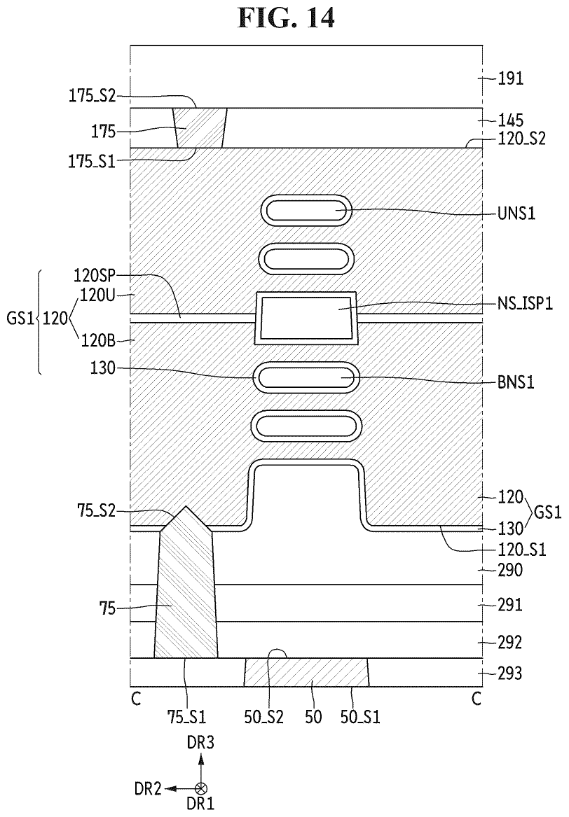

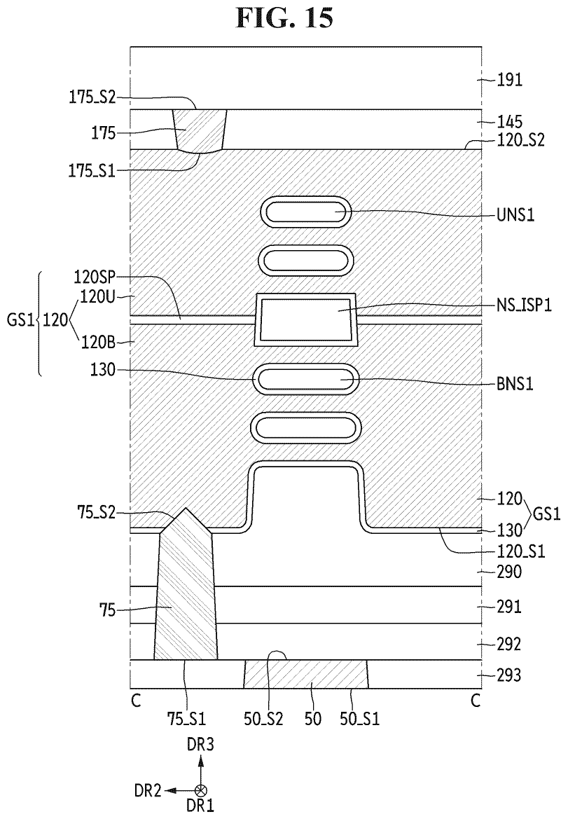

First gate structures GS1 may further include gate isolation patterns 120SP, which are disposed between first lower channel patterns BNS1 and first upper channel patterns UNS1. The gate isolation patterns 120SP may extend in the second direction DR2. For example, the gate isolation patterns 120SP may be disposed at a height level where first channel isolation patterns NS_ISP1 are located. For example, a gate isolation pattern 120SP may extend on either side of a corresponding first channel isolation pattern NS_ISP1 in the second direction DR2. The gate isolation pattern 120SP may contact a portion of the first gate insulating film 130 that surrounds the first channel isolation pattern NS_ISP1 when viewed in a cross section in the second direction DR2 (see, e.g., FIG. 14 or FIG. 15).

The gate isolation patterns 120SP may include, for example, at least one of silicon nitride, silicon oxynitride, silicon oxide, silicon oxycarbonitride, silicon boron nitride, silicon boron oxynitride, silicon oxycarbide, and a combination thereof.

First gate electrodes 120 may include lower gate electrodes 120B and upper gate electrodes 120U. The gate isolation patterns 120SP may be disposed between the lower gate electrodes 120B and the upper gate electrodes 120U. The gate isolation patterns 120SP may extend along the boundary between the lower gate electrodes 120B and the upper gate electrodes 120U. The lower gate electrodes 120B and the upper gate electrodes 120U may be separated from each other by the gate isolation patterns 120SP.

The lower gate electrodes 120B include first surface 120_S1 of the first gate electrodes 120. The upper gate electrodes 120U include second surface 120_S2 of the first gate electrodes 120.

The lower gate electrodes 120B surround the first lower channel patterns BNS1 and do not surround the first upper channel patterns UNS1. The upper gate electrodes 120U surround the first upper channel patterns UNS1 and do not surround the first lower channel patterns BNS1.

From a cross-sectional perspective, the lower gate electrodes 120B may surround parts of the gate isolation patterns 120SP. The upper gate electrodes 120U may surround other parts of the gate isolation patterns 120SP.

The first frontside gate contact 175 may be connected to the first gate electrodes 120. The first frontside gate contact 175 may be connected to the upper gate electrodes 120U. The first frontside gate contact 175 may be connected to the second surface 120_S2 of the first gate electrodes 120. For example, the first frontside gate contact 175 may contact the second surface 120_S2 of the upper gate electrode 120U.

The first frontside gate contact 175 may be disposed within first gate capping patterns 145. The first frontside gate contact 175 may penetrate the first gate capping patterns 145 and be in contact with the first gate electrodes 120. In a cross-sectional view cut in the second direction DR2, the first frontside gate contact 175 does not penetrate a first gate insulating film 130.

The first frontside gate contact 175 is illustrated as not overlapping with the first lower channel patterns BNS1 and the first upper channel patterns UNS1 in a third direction DR3, but the present disclosure is not limited thereto. Alternatively, contrary to what is illustrated, the first frontside gate contact 175 may overlap with the first lower channel patterns BNS1 and the first upper channel patterns UNS1 in the third direction DR3.

The first frontside gate contact 175 may include a first surface 175_S1 and a second surface 175_S2 that are opposite to each other in the third direction DR3. The first surface 175_S1 of the first frontside gate contact 175 may face the first gate electrodes 120.

The first surface 175_S1 of the first frontside gate contact 175 may be in contact with the upper gate electrodes 120U. The first surface 175_S1 of the first frontside gate contact 175 may be in contact with the second surface 120_S2 of the first gate electrode 120. The first surface 175_S1 of the first frontside gate contact 175 may be the contact surface of the first frontside gate contact 175 that contacts the first gate electrodes 120.

As illustrated in FIG. 14, the first surface 175_S1 of the first frontside gate contact 175 may be a flat surface.

Alternatively, as illustrated in FIG. 15, the first surface 175_S1 of the first frontside gate contact 175 may be a convex surface. For example, the first surface 175_S1 may be curved or angled such that a middle portion in the second direction DR2 is at a lower vertical level than the edge portions in the second direction DR2

A first backside gate contact 75 may be connected to the lower gate electrodes 120B. The first backside gate contact 75 may be in contact with the lower gate electrodes 120B.

Referring to FIG. 16, in the semiconductor device according to some embodiments, a second surface 75_S2 of the first backside gate contact 75 may have a convex shape in a cross-sectional view cut in the first direction DR1. For example, the second surface 75_S2 may be curved such that a middle portion in the first direction DR1 is at a higher vertical level than the edge portions in the first direction DR1.

For example, in a cross-sectional view cut in the first direction DR1, the second surface 75_S2 of the first backside gate contact 75 may have a wedge shape.

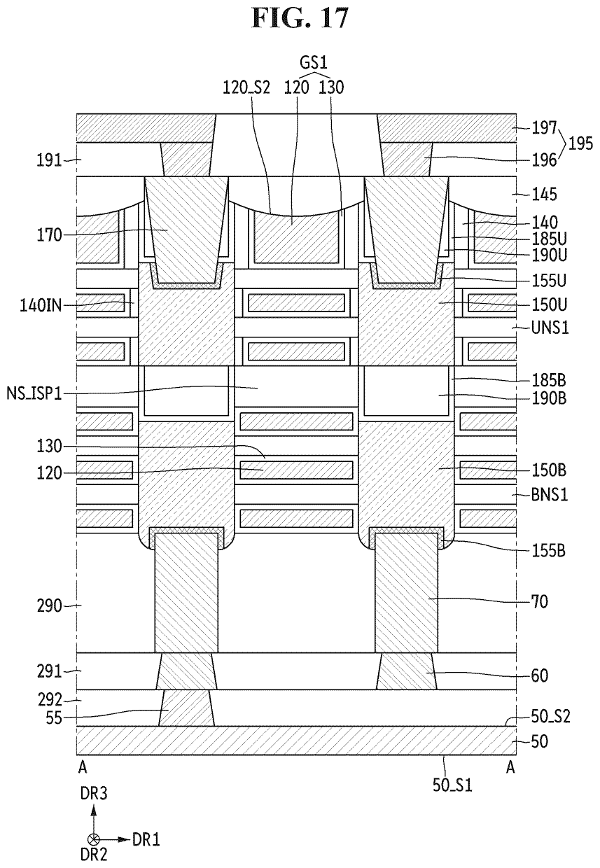

Referring to FIG. 17, the semiconductor device according to some embodiments may further include inner spacers 140IN, which are disposed between first gate structures GS1 and first upper source/drain patterns 150U.

The inner spacers 140IN may be disposed between each pair of adjacent first upper channel patterns UNS1 in a third direction DR3 and between the first upper channel patterns UNS1 and first channel isolation patterns NS_ISP1 in the third direction DR3. The inner spacers 140IN may be in contact with the first upper source/drain patterns 150U. The first gate structures GS1 between each pair of adjacent first upper channel patterns UNS1 and between the first upper channel patterns UNS1 and the first channel isolation patterns NS_ISP1 may not be in contact with the first upper source/drain patterns 150U.

The inner spacers 140IN may not be disposed between the first gate structures GS1 and first lower source/drain patterns 150B. The inner spacers 140IN may include an insulating material.

Alternatively, for example, the inner spacers 140IN may be disposed between the first gate structures GS1 and the first lower source/drain patterns 150B. The inner spacers 140IN may not be disposed between the first gate structures GS1 and the first upper source/drain patterns 150U. In another example, the inner spacers 140IN may be disposed between the first gate structures GS1 and the first lower source/drain patterns 150B and between the first gate structures GS1 and the first upper source/drain patterns 150U.

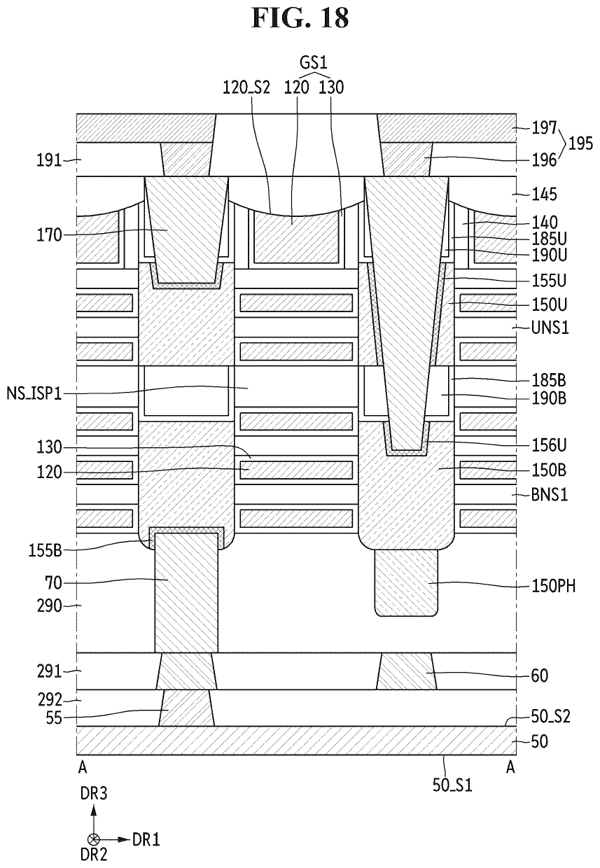

Referring to FIG. 18, in the semiconductor device according to some embodiments, at least one first frontside source/drain contact 170 may be connected to both a first upper source/drain pattern 150U and a first lower source/drain pattern 150B.

The first upper source/drain pattern 150U and the first lower source/drain pattern 150B may be connected to each other by the first frontside source/drain contact 170. An additional first upper contact silicide film 156U may be disposed between the first lower source/drain pattern 150B and the first frontside source/drain contact 170.

For example, a first backside source/drain contact 70 may not be disposed below the first lower source/drain pattern 150B connected to the first frontside source/drain contact 170. A sacrificial epitaxial pattern 150PH may be disposed below the first lower source/drain pattern 150B connected to the first frontside source/drain contact 170. The sacrificial epitaxial pattern 150PH may be disposed within a first backside interlayer insulating film 290. The sacrificial epitaxial pattern 150PH may include a semiconductor material.

Alternatively, for example, the sacrificial epitaxial pattern 150PH may not be disposed below the first lower source/drain pattern 150B connected to the first frontside source/drain contact 170. Yet alternatively, in another example, the first backside source/drain contact 70 may be disposed below the first lower source/drain pattern 150B connected to the first frontside source/drain contact 170. The first backside source/drain contact 70 connected to the first frontside source/drain contact 170 may not be connected to a backside wiring line 50.

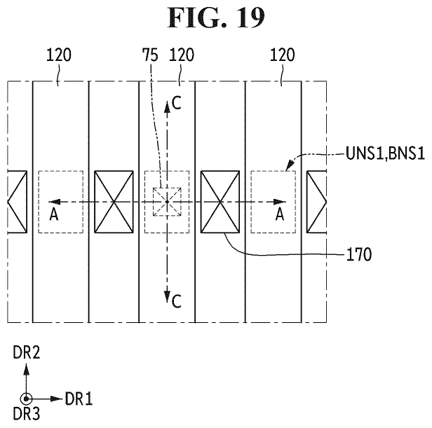

FIGS. 19 to 21 are diagrams illustrating a semiconductor device according to some embodiments. For the convenience of explanation, the embodiment of FIGS. 19 to 21 will hereinafter be described, focusing on the differences from what has been described above with reference to FIGS. 1 to 6.

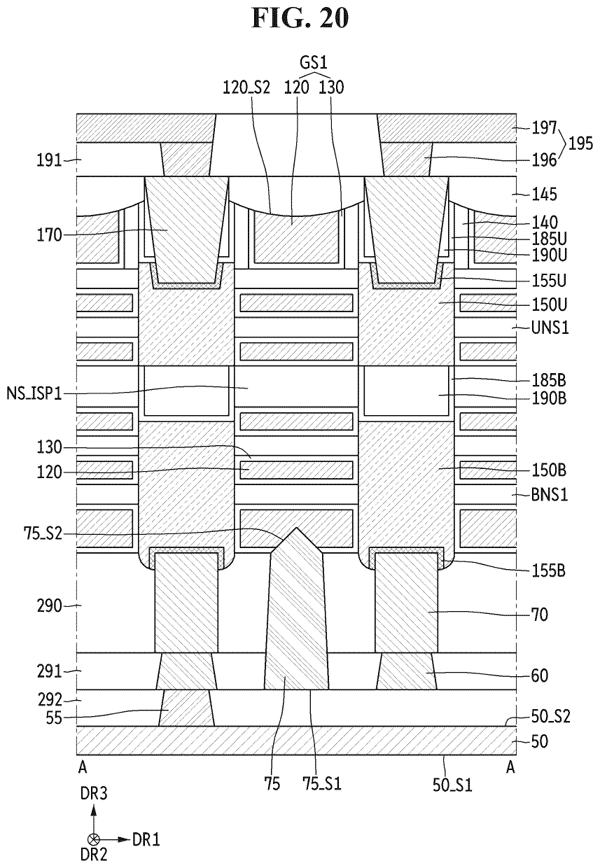

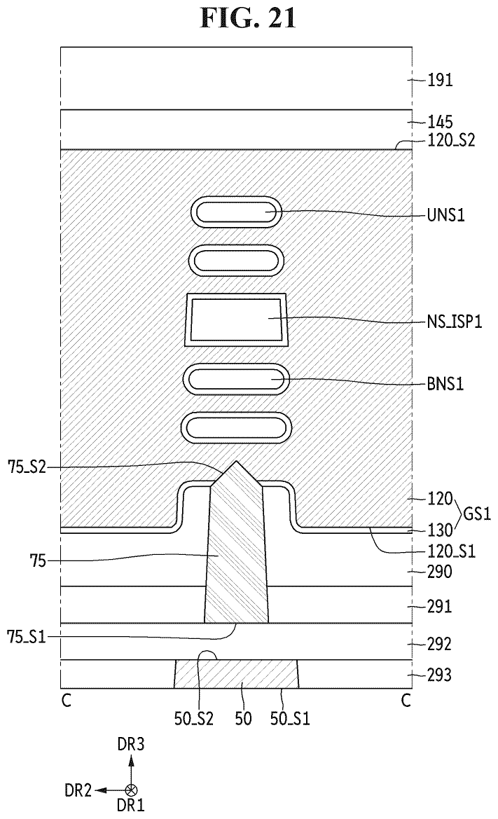

For reference, FIG. 19 is an example layout view illustrating a semiconductor device according to some embodiments. FIGS. 20 and 21 are example cross-sectional views taken along A-A and C-C of FIG. 19, respectively.

Referring to FIGS. 19 to 21, in the semiconductor device according to some embodiments, a first backside gate contact 75 may be connected to a first gate electrode 120 in an active region.

The first backside gate contact 75 may overlap with first lower channel patterns BNS1 and first upper channel patterns UNS1 in the third direction DR3.

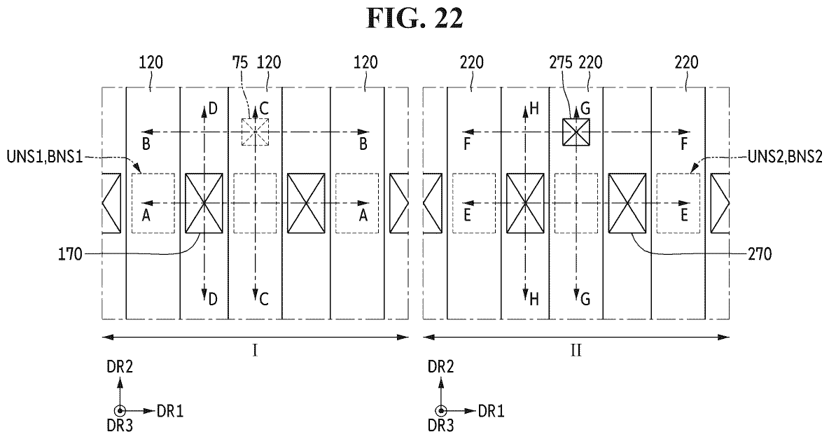

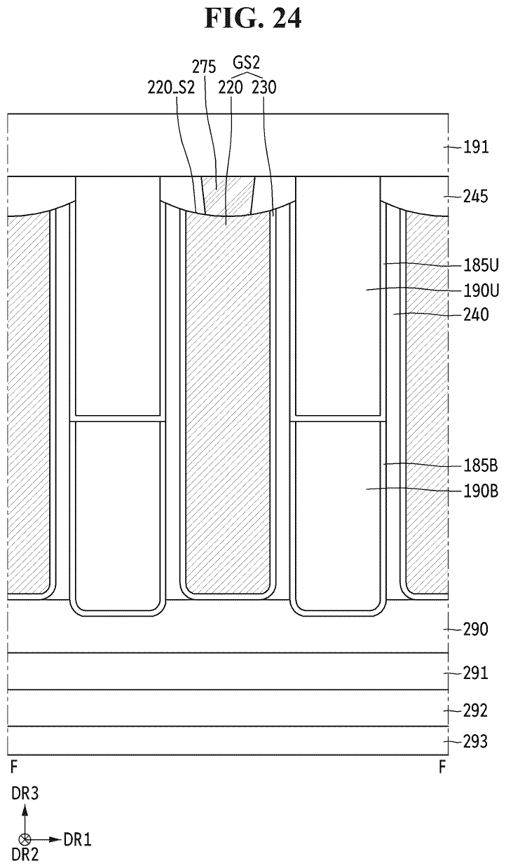

FIGS. 22 to 26 are diagrams illustrating a semiconductor device according to some embodiments.

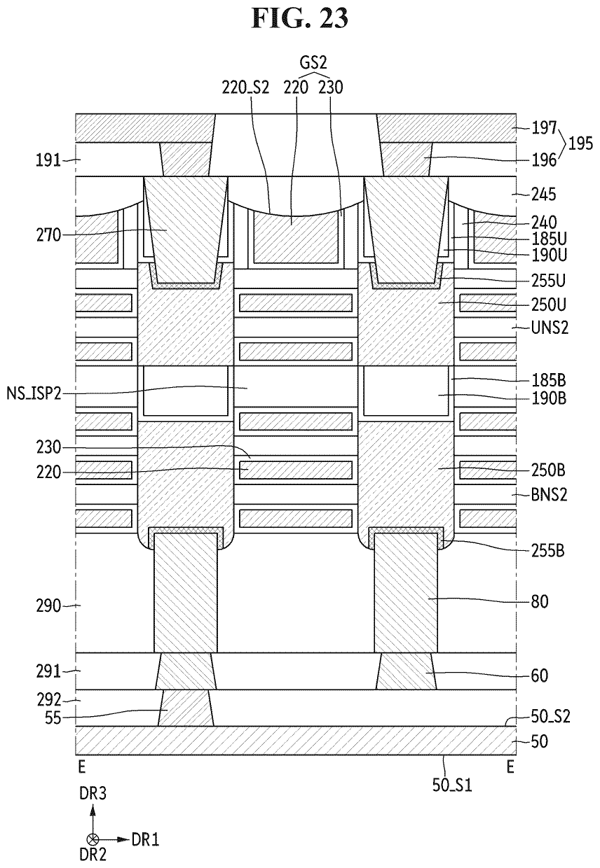

For reference, FIG. 22 is an example layout view for explaining a semiconductor device according to some embodiments. FIGS. 23, 24, 25, and 26 are example cross-sectional views taken along lines E-E, F-F, G-G, and H-H, respectively, of FIG. 22.

Additionally, the description of a first region I of FIG. 22 may be substantially the same as described above with reference to FIGS. 1 to 18. Therefore, a second region II of FIG. 22 will hereinafter be described. Moreover, features of the second region II that coincide with those of the first region I will be omitted or briefly explained.

Referring to FIGS. 22 to 26, the semiconductor device according to some embodiments may include first lower channel patterns BNS1, first upper channel patterns UNS1, second lower channel patterns BNS2, second upper channel patterns UNS2, first gate structures GS1, second gate structures GS2, first lower source/drain patterns 150B, first upper source/drain patterns 150U, second lower source/drain patterns 250B, second upper source/drain patterns 250U, first frontside source/drain contacts 170, second frontside source/drain contacts 270, first backside source/drain contacts 70, second backside source/drain contacts 80, a first backside gate contact 75, and a second frontside gate contact 275.

The semiconductor device according to some embodiments may include the first and second regions I and II. The first and second regions I and II may be adjacent to each other or may be spaced apart from each other. The first and second regions I and II may perform the same functions or perform different functions.

The first lower channel patterns BNS1, the first upper channel patterns UNS1, the first gate structures GS1, the first lower source/drain patterns 150B, the first upper source/drain patterns 150U, the first frontside source/drain contacts 170, the first backside source/drain contact 70, and the first backside gate contact 75 may be disposed in the first region I of the semiconductor device according to some embodiments.

The second lower channel patterns BNS2, the second upper channel patterns UNS2, the second gate structures GS2, the second lower source/drain patterns 250B, the second upper source/drain patterns 250U, the second frontside source/drain contacts 270, the second backside source/drain contact 80, and the second frontside gate contact 275 may be disposed in the second region II.

At least one second lower channel pattern BNS2 may be disposed on a first backside interlayer insulating film 290. At least one second upper channel pattern UNS2 may be disposed on the upper surface of the first backside interlayer insulating film 290. The second upper channel patterns UNS2 may be spaced apart from the second lower channel patterns BNS2 in the third direction DR3.

For example, the second lower channel patterns BNS2 may include the same material as the first lower channel patterns BNS1. The second upper channel patterns UNS2 may include the same material as the first upper channel patterns UNS1. The first lower channel patterns BNS1 and the second lower channel patterns BNS2 may be included in transistors of the same conductivity type. The first upper channel patterns UNS1 and the second upper channel patterns UNS2 may be included in transistors of the same conductivity type. For example, the conductivity type of the first lower channel patterns BNS1 and the second lower channel patterns BNS2 may be different from the conductivity type of the first upper channel patterns UNS1 and the second upper channel patterns UNS2.

Second channel isolation patterns NS_ISP2 may be disposed between the second lower channel patterns BNS2 and the second upper channel patterns UNS2. The second channel isolation patterns NS_ISP2 may be spaced apart from the second lower channel patterns BNS2 in the third direction DR3. The second channel isolation patterns NS_ISP2 may be spaced apart from the second upper channel patterns UNS2 in the third direction DR3. If the first channel isolation patterns NS_ISP1 are not disposed in the first region I, the second channel isolation patterns NS_ISP2 may not be disposed in the second region II.

A plurality of second gate structures GS2 may be disposed on the first backside interlayer insulating film 290. The second gate structures GS2 may extend longitudinally in the second direction DR2. Alternatively, contrary to what is illustrated, the second gate structures GS2, unlike the first gate structures GS1, may extend longitudinally in the first direction DR1. In this case, the second gate structures GS2 may be spaced apart from each other in the second direction DR2.

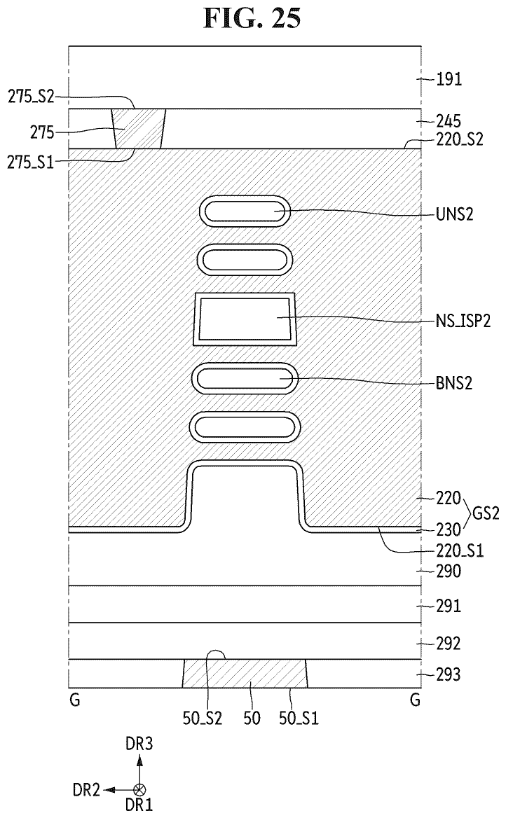

The second gate structures GS2 may surround the second lower channel patterns BNS2 and the second upper channel patterns UNS2 when viewed in cross section taken in the second direction DR2 (see, e.g., FIG. 25). The second gate structures GS2 may surround the second channel isolation patterns NS_ISP2. The second gate structures GS2 may include second gate electrodes 220 and a second gate insulating film 230.

The second gate electrodes 220 may be disposed on the first backside interlayer insulating film 290. The second gate electrodes 220 may extend in the second direction DR2. The second gate electrodes 220 may surround the second lower channel patterns BNS2, the second upper channel patterns UNS2, and the second channel isolation patterns NS_ISP2.

The second gate electrodes 220 may each have a first surface 220_S1 and a second surface 220_S2 that are opposite to each other in the third direction DR3. The first surface 220_S1 of the second gate electrodes 220 may face the first backside interlayer insulating film 290.

The second gate insulating film 230 may be disposed between the second gate electrodes 220 and the second backside interlayer insulating film 290. The second gate insulating film 230 may extend along the upper surface of the first backside interlayer insulating film 290. The second gate insulating film 230 may extend along the first surface 220_S1 of the second gate electrodes 220. The second gate insulating film 230 may not extend along the second surface 220_S2 of the second gate electrodes 220.

The second gate insulating film 230 may be disposed between the second lower channel patterns BNS2 and the second gate electrodes 220, between the second upper channel patterns UNS2 and the second gate electrodes 220, and between the second channel isolation patterns NS_ISP2 and the second gate electrodes 220.

The second gate spacers 240 may be disposed on the sidewalls of the second gate electrodes 220. The second gate capping patterns 245 may be disposed on the second surface 220_S2 of the second gate electrodes 220.

The second lower source/drain patterns 250B may be disposed on the first backside interlayer insulating film 290. The second lower source/drain patterns 250B are connected to the second lower channel patterns BNS2. The second lower source/drain patterns 250B are in contact with the second lower channel patterns BNS2.

The second upper source/drain patterns 250U may be disposed on the second lower source/drain patterns 250B. The second upper source/drain patterns 250U may be spaced apart from the second lower source/drain patterns 250B in the third direction DR3.

The second upper source/drain patterns 250U are connected to the second upper channel patterns UNS2. The second upper source/drain patterns 250U are in contact with the second upper channel patterns UNS2.

The second lower source/drain patterns 250B and the second upper source/drain patterns 250U may each include epitaxial patterns. The second lower source/drain patterns 250B and the second upper source/drain patterns 250U may each include a semiconductor material.

The second frontside source/drain contacts 270 may be connected to the second upper source/drain patterns 250U. For example, the second frontside source/drain contacts 270 may be electrically connected to the second upper source/drain patterns 250U. The second frontside source/drain contacts 270 may be connected to a frontside wiring structure 195.

The second backside source/drain contacts 80 may be connected to the second lower source/drain patterns 250B. For example, the second backside source/drain contacts 80 may be electrically connected to the second lower source/drain patterns 250B.

The second backside source/drain contacts 80 may overlap with the second lower source/drain patterns 250B in the third direction DR3. The second backside source/drain contacts 80 connect the second lower source/drain patterns 250B to a backside wiring line 50.

A second upper contact silicide film 255U may be disposed between the second frontside source/drain contacts 270 and the second upper source/drain patterns 250U. A second lower contact silicide film 255B may be disposed between the second backside source/drain contacts 80 and the second lower source/drain patterns 250B.

A backside connection via 55 and backside connection contacts 60 may be connected to the second backside source/drain contacts 80.

The second frontside gate contact 275 may be connected to a second gate electrode 220. The second frontside gate contacts 275 may be connected to the second surface 220_S2 of the second gate electrode 220.

The second frontside gate contact 275 may be disposed within a second gate capping pattern 245. The second frontside gate contact 275 may penetrate the second gate capping pattern 245 and be in contact with the second gate electrode 220. In a cross-sectional view cut in the second direction DR2, the second frontside gate contact 275 does not penetrate the second gate insulating film 230.

The second frontside gate contact 275 is illustrated as not overlapping with the second lower channel patterns BNS2 and the second upper channel patterns UNS2 in the third direction DR3, but the present disclosure is not limited thereto. Alternatively, the second frontside gate contact 275 may overlap with the second lower channel patterns BNS2 and the second upper channel patterns UNS2 in the third direction DR3.

The second frontside gate contact 275 may include a first surface 275_S1 and a second surface 275_S2 that are opposite each other in the third direction DR3. The first surface 275_S1 of the second frontside gate contact 275 may face the second gate electrode 220.

The first surface 275_S1 of the second frontside gate contact 275 may be in contact with the second gate electrode 220. The first surface 275_S1 of the second frontside gate contact 275 may be in contact with the second surface 220_S2 of the second gate electrode 220. The first surface 275_S1 of the second frontside gate contact 275 may be the contact surface of the second frontside gate contact 275 that is in contact with the second gate electrode 220.

In a cross-sectional view cut in the second direction DR2, the first surface 275_S1 of the second frontside gate contact may be a flat surface. Alternatively, in a cross-sectional view cut in the second direction DR2, the first surface 275_S1 of the second frontside gate contact 275 may be a convex surface.

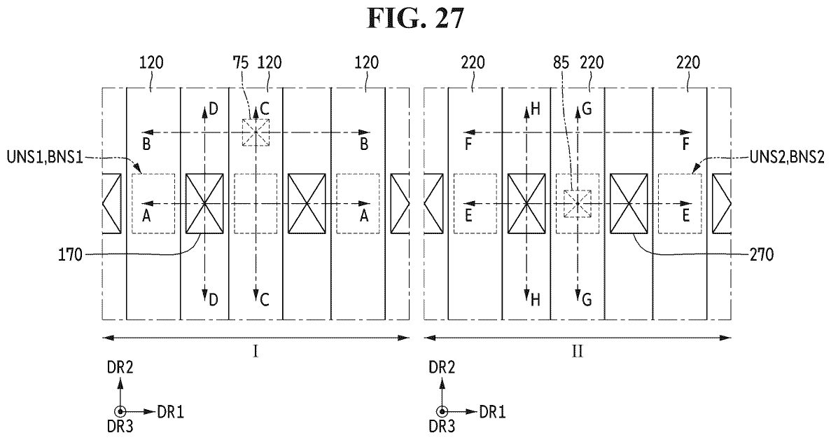

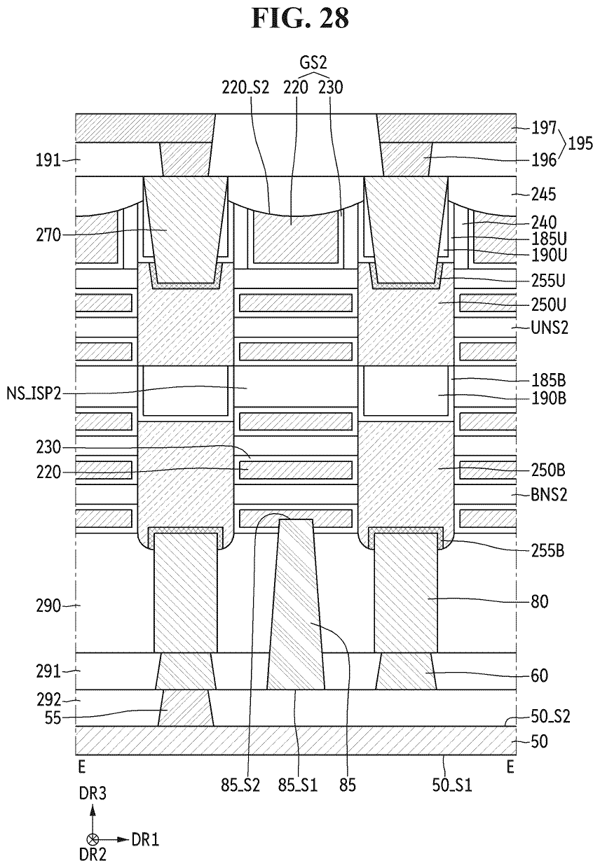

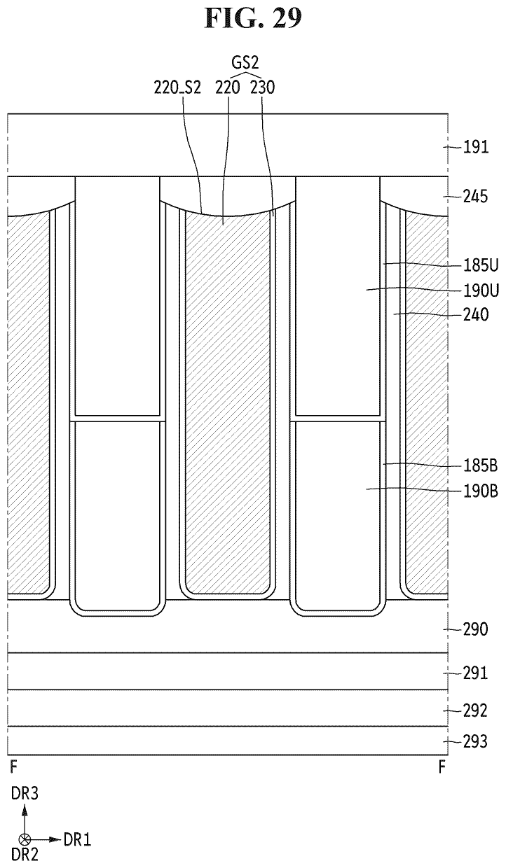

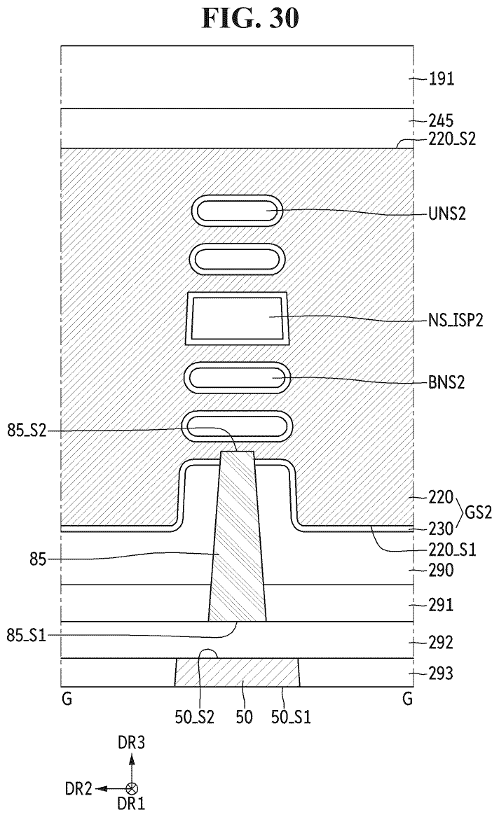

FIGS. 27 to 30 are diagrams illustrating a semiconductor device according to some embodiments. For the convenience of explanation, the embodiment of FIGS. 27 to 30 will hereinafter be described, focusing on the differences from what has been described above with reference to FIGS. 22 to 26.

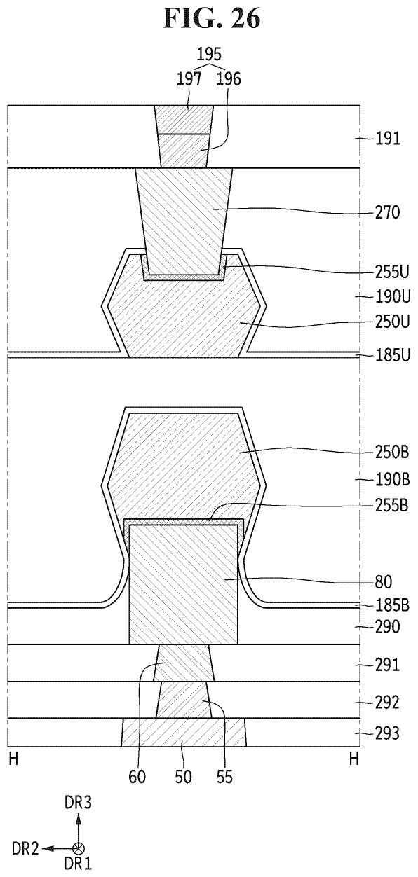

A cross-sectional view taken along line H-H of FIG. 27 may be substantially the same as that of FIG. 26.

Referring to FIGS. 27 to 30, the semiconductor device according to some embodiments may further include a second backside gate contact 85.

The second backside gate contact 85 may extend in a third direction DR3. The second backside gate contact 85 may penetrate a second gate insulating film 230 on a first surface 220_S1 of a second gate electrode 220. The second backside gate contact 85 may be connected to the second gate electrode 220. The second backside gate contact 85 may be in contact with the second gate electrode 220. The second gate electrode 220 may be connected to the second backside gate contact 85 rather than to a second frontside gate contact (e.g., “275” in FIG. 25).

The second backside gate contact 85 may be disposed within first and second backside interlayer insulating films 290 and 291. Although not illustrated, the second backside gate contact 85 may be connected to a backside wiring line 50.

For example, the second backside gate contact 85 may be connected to the second gate electrode 220 in an active region. The second backside gate contact 85 may overlap with the second lower channel patterns BNS2 and the second upper channel patterns UNS2 in the third direction DR3.

The second backside gate contact 85 may have a first surface 85_S1 and a second surface 85_S2 that are opposite each other in the third direction DR3. The second surface 85_S2 of the second backside gate contact 85 may face the second gate electrode 220.

The second surface 85_S2 of the second backside gate contact 85 may be in contact with the second gate electrode 220. The second surface 85_S2 of the second backside gate contact 85 may be in contact with the first surface 220_S1 of the second gate electrode 85. The second surface 85_S2 of the second backside gate contact 85 may be the contact surface of the second backside gate contact 85 that is in contact with the second gate electrode 220.

In cross-sectional views cut in first and second directions DR1 and DR2, the second surface 85_S2 of the second backside gate contact 85 may be a flat surface.

Alternatively, in cross-sectional views cut in the first and second directions DR1 and DR2, the second surface 85_S2 of the second backside gate contact 85 may be a convex surface. Based on the description of the first backside gate contact 75 of FIG. 6, the ratio of the contact depth to the contact width of the second backside gate contact 85 may be 0.1 or less.

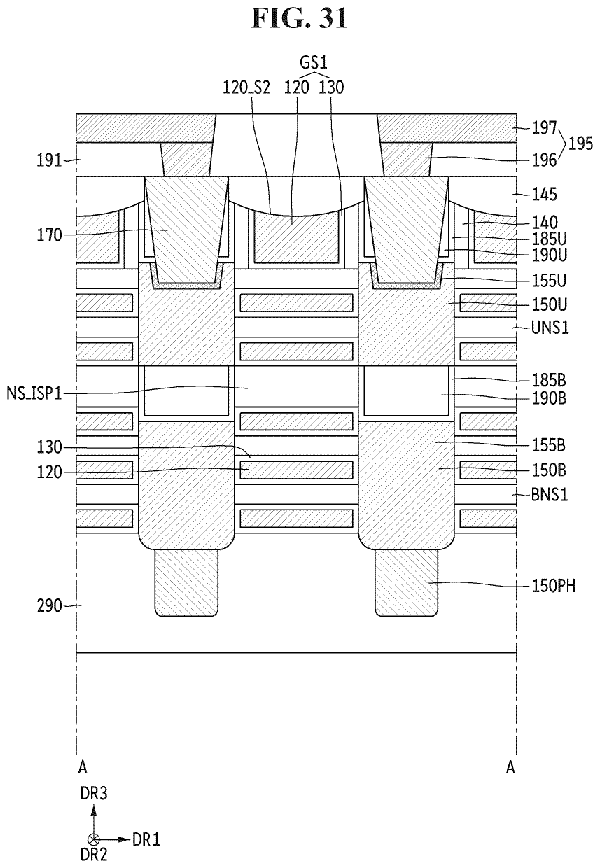

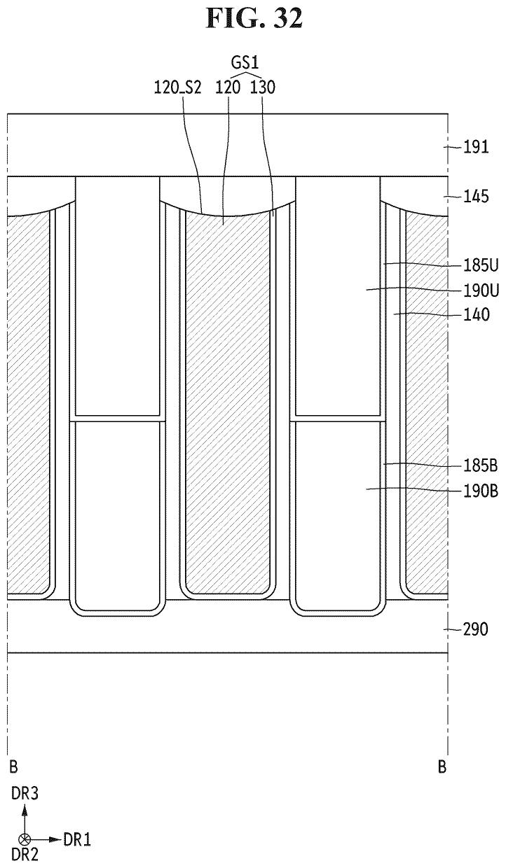

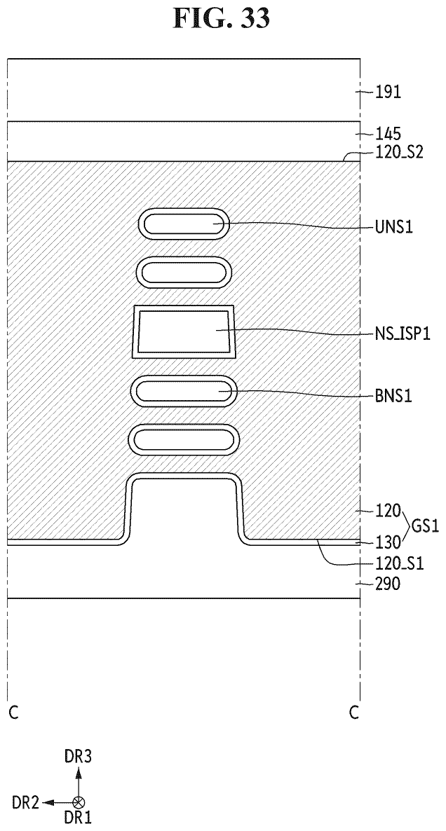

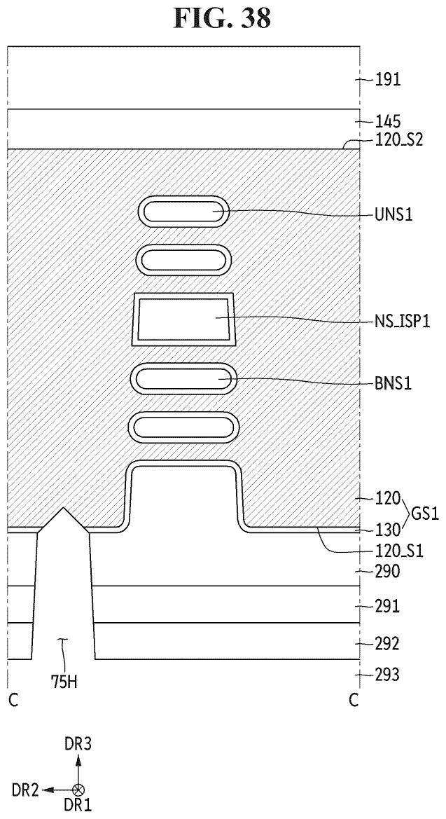

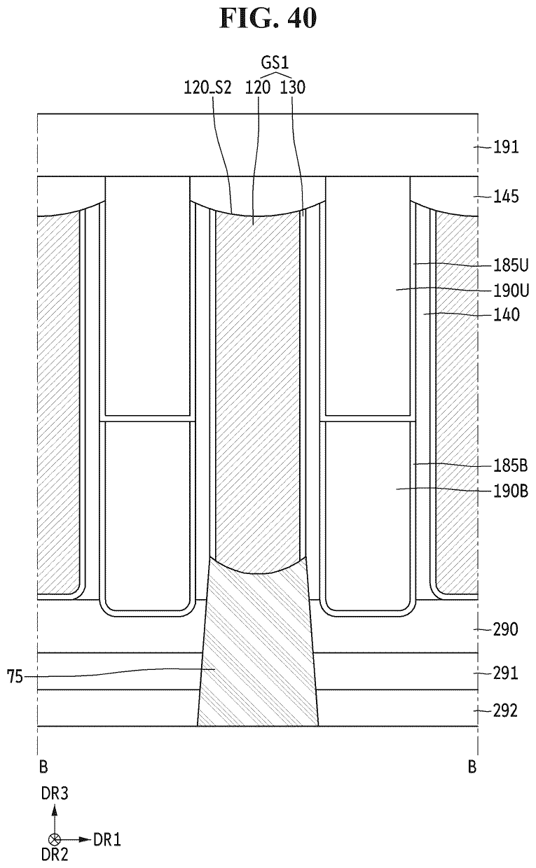

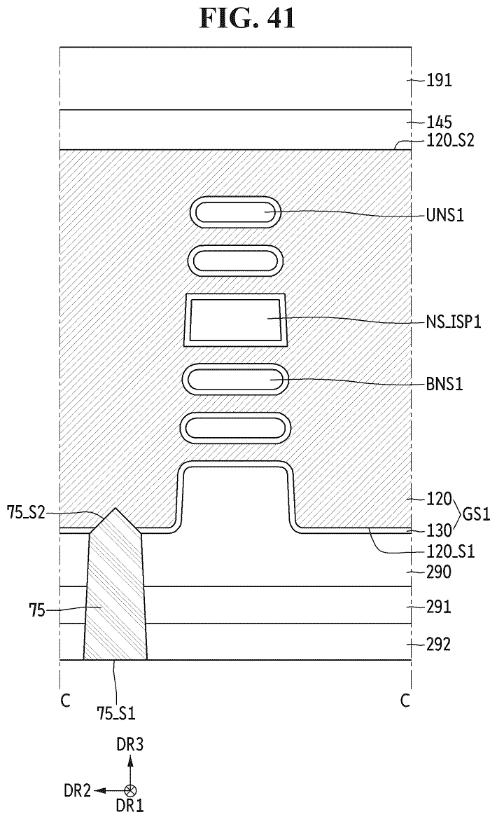

FIGS. 31 to 41 are diagrams illustrating intermediate steps of a method for manufacturing a semiconductor device according to some embodiments.

Referring to FIGS. 31 to 33, first lower channel patterns BNS1, first upper channel patterns UNS1, first gate structures GS1, first lower source/drain patterns 150B, first upper source/drain patterns 150U, first intermediate insulating patterns NS_ISP1, and first frontside source/drain contacts 170 may be formed on a substrate.

The substrate may include bulk silicon or silicon-on-insulator (SOI). Alternatively, the substrate may be an Si substrate, or may include other materials such as silicon-germanium (SiGe), SiGe-on-insulator (SGOI), indium antimonide, a lead telluride compound, indium arsenide, indium phosphide, gallium arsenide, or gallium antimonide, but it is not limited thereto.

Sacrificial epitaxial patterns 150PH may be formed in the substrate. Before forming the first lower source/drain patterns 150B and the first upper source/drain patterns 150U, the sacrificial epitaxial patterns 150PH may be formed in the substrate.

Alternatively, the sacrificial epitaxial patterns 150PH may not be formed.

Thereafter, the substrate may be removed to expose the first gate structures GS1, the first lower source/drain patterns 150B, and the sacrificial epitaxial patterns 150PH.

Thereafter, a first backside interlayer insulating film 290 may be formed on the first gate structures GS1, the first lower source/drain patterns 150B, and the sacrificial epitaxial patterns 150PH. The first backside interlayer insulating film 290 may include a field insulating film formed before forming the first lower source/drain patterns 150B and the first upper source/drain patterns 150U.

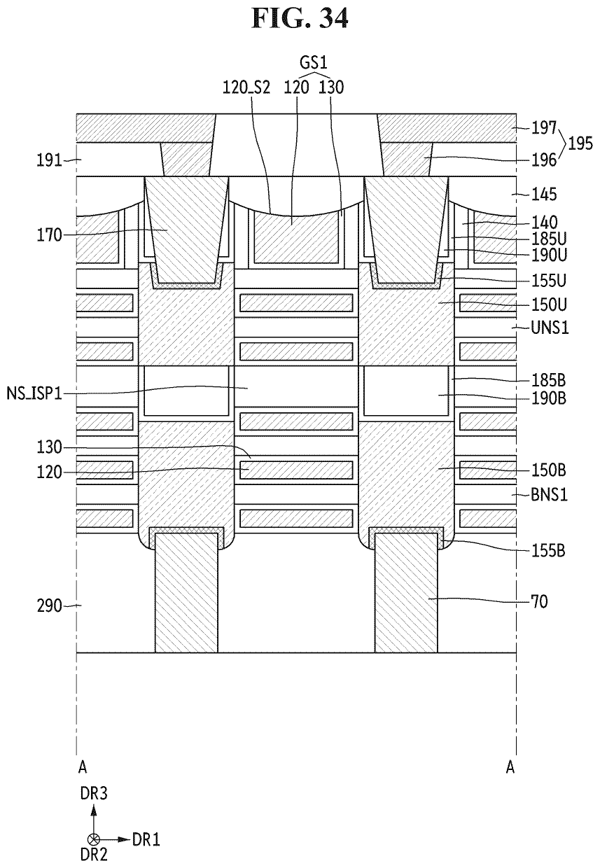

Referring to FIG. 34, first backside source/drain contacts 70 may be formed in the first backside interlayer insulating film 290.

Specifically, through an etching process, the sacrificial epitaxial patterns 150PH of FIG. 31 may be exposed. By removing the exposed sacrificial epitaxial patterns 150PH, the first lower source/drain patterns 150B may be exposed. Thereafter, the first backside source/drain contacts 70 connected to the first lower source/drain patterns 150B may be formed.

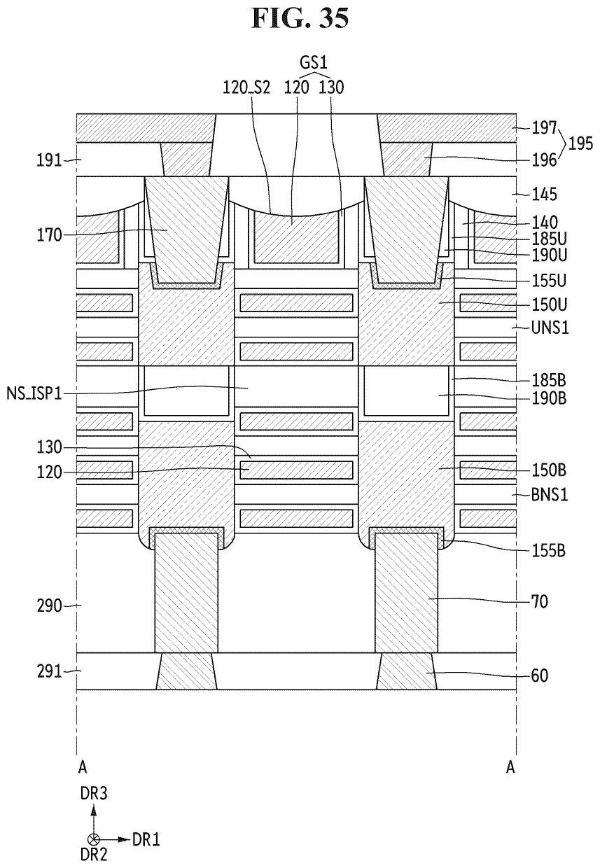

Referring to FIG. 35, backside connection contacts 60 may be formed.

The backside connection contacts 60 may be connected to the first backside source/drain contacts 70. The backside connection contacts 60 may be formed within the second backside interlayer insulating film 291.

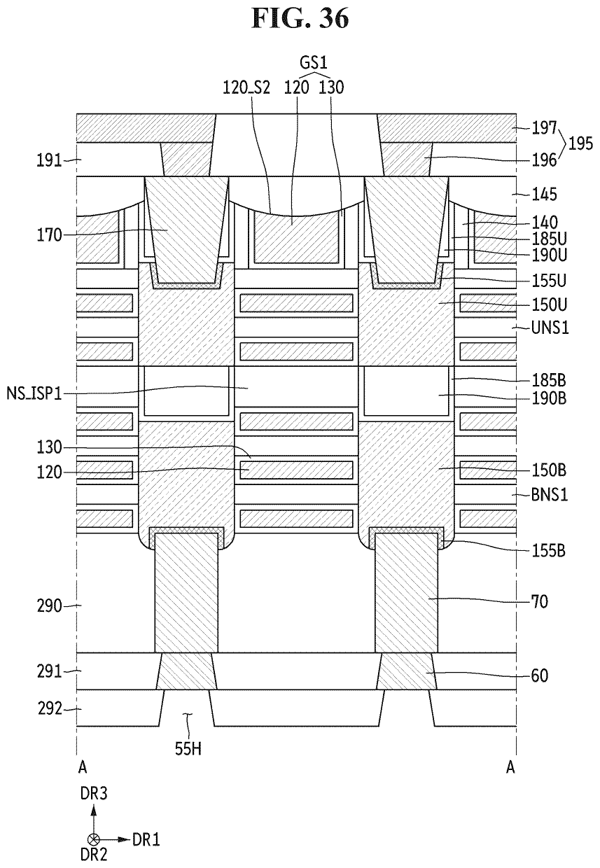

Referring to FIGS. 36 to 38, a third backside interlayer insulating film 292 may be formed on the backside connection contacts 60 and the second backside interlayer insulating film 291.

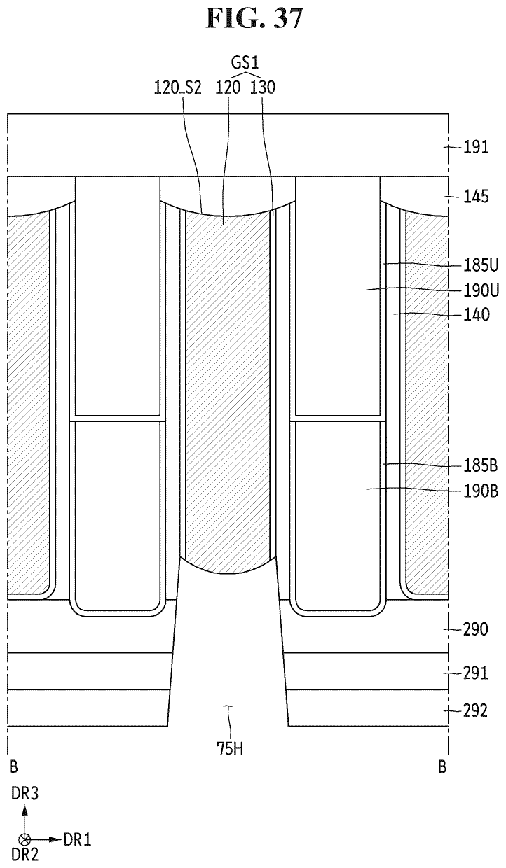

Thereafter, backside connection via holes 55H (see, e.g., FIG. 36) and a backside gate contact hole 75H (see, e.g., FIGS. 36 and 37) may be formed. The backside connection via holes 55H may expose the backside connection contacts 60. The backside gate contact hole 75H may penetrate a first gate insulating film 130 to expose first gate electrodes 120.

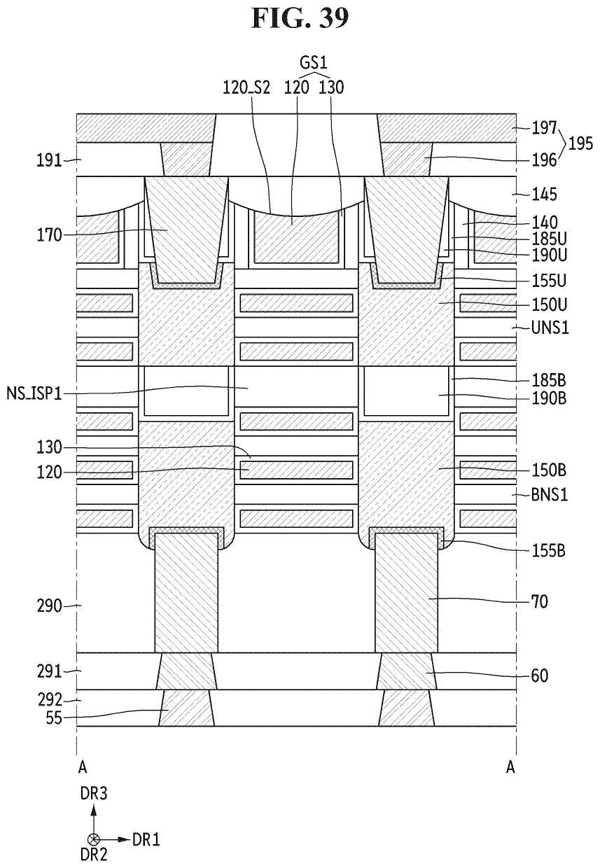

Referring to FIGS. 39 to 41, a first backside gate contact 75 may be formed in the backside gate contact hole 75H.

The first backside gate contact 75 may fill the backside gate contact hole 75H. The first backside gate contact 75 may be connected to a first gate electrode 120. The first backside gate contact 75 may contact a first gate electrode 120.

Backside connection via 55 may be formed in the backside connection via holes 55H. The backside connection vias 55 may fill the backside connection via holes 55H. The backside connection vias 55 may be connected to the backside connection contacts 60. The backside connection vias 55 may contact the backside connection contacts 60.

Alternatively, contrary to what has been described with reference to FIGS. 36 to 41, the first backside gate contact 75 connected to the first gate electrode 120 may be formed before the formation of the backside connection via holes 55H. Alternatively, the backside gate contact hole 75H may be formed after the formation of the backside connection vias 55.

Thereafter, referring again to FIG. 2, a backside wiring line 50 connected to the first backside source/drain contact 70 may be formed.

In concluding the detailed description, those skilled in the art will appreciate that many variations and modifications may be made to the preferred embodiments without substantially departing from the principles of the present disclosure. Therefore, the disclosed preferred embodiments of the disclosure are used in a generic and descriptive sense only and not for purposes of limitation.

What is claimed is:

1. A semiconductor device comprising:
a first channel pattern and a second channel pattern spaced apart in a first direction;
a gate structure surrounding the first channel pattern and the second channel pattern, the gate structure extending in a second direction and including a gate insulating film and a gate electrode; and
a backside gate contact penetrating the gate insulating film and including a contact surface that contacts the gate electrode, wherein
the gate electrode has a first surface and a second surface opposite to each other in the first direction,
the gate insulating film extends along the first surface of the gate electrode, and
in a cross-sectional view in the second direction, the contact surface of the backside gate contact includes a first inclined flat surface and a second inclined flat surface that are inclined with respect to the first direction.

2. The semiconductor device of claim 1, wherein the first inclined flat surface and the second inclined flat surface of the backside gate contact are directly connected to each other.

3. The semiconductor device of claim 1, wherein
the contact surface of the backside gate contact further includes a contact connecting surface that connects the first inclined flat surface to the second inclined flat surface, and
the contact connecting surface has a curved shape such that a middle portion of the contact connecting surface is at a higher vertical level than edge portions of the contact connecting surface.

4. The semiconductor device of claim 1, wherein, in a cross-sectional view in a third direction perpendicular to both the first direction and the second direction, the contact surface of the backside gate contact has a shape such that a middle portion of the contact surface is at a higher vertical level than edge portions of the contact surface.

5. The semiconductor device of claim 1, wherein, in a cross-sectional view in a third direction perpendicular to both the first direction and the second direction, the contact surface of the backside gate contact has a shape such that a middle portion of the contact surface is at a lower vertical level than edge portions of the contact surface.

6. The semiconductor device of claim 1, wherein an angle between the first inclined flat surface and the second inclined flat surface is between 60 degrees and 120 degrees.

7. The semiconductor device of claim 1, further comprising:
a first source/drain pattern connected to the first channel pattern; and
a second source/drain pattern connected to the second channel pattern and spaced apart from the first source/drain pattern in the first direction.

8. The semiconductor device of claim 1, further comprising:
a channel isolation pattern disposed between the first channel pattern and the second channel pattern,
wherein the gate structure surrounds the channel isolation pattern in the cross-sectional view in the second direction.

9. The semiconductor device of claim 1, wherein
the gate structure further includes a gate isolation pattern disposed between the first channel pattern and the second channel pattern and extending in the second direction,
the gate electrode includes a first gate electrode surrounding the first channel pattern and a second gate electrode surrounding the second channel pattern in the cross-sectional view in the second direction, and
the gate isolation pattern is disposed between the first gate electrode and the second gate electrode.

10. The semiconductor device of claim 1, further comprising:
a frontside gate contact connected to the second surface of the gate electrode and including a contact surface that contacts the gate electrode,
wherein, in the cross-sectional view in the second direction, the contact surface of the frontside gate contact is a flat surface or a surface such that a middle portion of the contact surface is at a lower vertical level than edge portions of the contact surface.

11. A semiconductor device comprising:
a first channel pattern and a second channel pattern spaced apart in a first direction;
a gate structure surrounding the first channel pattern and the second channel pattern, the gate structure extending in a second direction and including a gate insulating film and a gate electrode; and
a backside gate contact penetrating the gate insulating film and including a contact portion that contacts the gate electrode, wherein
the gate electrode has a first surface and a second surface opposite to each other in the first direction,
the gate insulating film extends along the first surface of the gate electrode,
in a cross-sectional view in the second direction, the contact portion of the backside gate contact has a contact width in the second direction and a contact depth in the first direction, and
a ratio of the contact depth to the contact width is between 0.25 and 1.

12. The semiconductor device of claim 11, wherein
the contact portion of the backside gate contact includes a contact surface that contacts the gate electrode, and
in a cross-sectional view in the second direction, the contact surface of the backside gate contact includes a first inclined flat surface and a second inclined flat surface.

13. The semiconductor device of claim 12, wherein, in a cross-sectional view in a third direction perpendicular to both the first direction and the second direction, the contact surface of the backside gate contact has a shape such that a middle portion of the contact surface is at a higher vertical level than edge portions of the contact surface.

14. The semiconductor device of claim 12, wherein, in a cross-sectional view in a third direction perpendicular to both the first direction and the second direction, the contact surface of the backside gate contact has a shape such that a middle portion of the contact surface is at a lower vertical level than edge portions of the contact surface.

15. The semiconductor device of claim 11, further comprising:
a first source/drain pattern connected to the first channel pattern; and
a second source/drain pattern connected to the second channel pattern and spaced apart from the first source/drain pattern in the first direction.

16. The semiconductor device of claim 11, further comprising:
a channel isolation pattern disposed between the first channel pattern and the second channel pattern,
wherein the gate structure surrounds the channel isolation pattern.

17. The semiconductor device of claim 11, wherein the backside gate contact does not overlap with the first channel pattern and the second channel pattern in the first direction.

18. A semiconductor device comprising:
a first lower channel pattern and a first upper channel pattern spaced apart from each other in a first direction;
a first gate structure surrounding the first lower channel pattern and the first upper channel pattern, the first gate structure extending in a second direction and including a first gate insulating film and a first gate electrode, wherein the first gate electrode has a first surface and a second surface opposite to each other in the first direction and the first gate insulating film extends along the first surface of the first gate electrode;
a second lower channel pattern and a second upper channel pattern spaced apart from each other in the first direction;
a second gate structure surrounding the second lower channel pattern and the second upper channel pattern, the second gate structure extending in the second direction and including a second gate insulating film and a second gate electrode, wherein the second gate electrode has a third surface and a fourth surface opposite to each other in the first direction and the second gate insulating film extends along the third surface of the second gate electrode;
a backside gate contact penetrating the first gate insulating film and including a first contact surface that contacts the first gate electrode; and
a frontside gate contact including a second contact surface that contacts the fourth surface of the second gate electrode, wherein
in a cross-sectional view in the second direction, the first contact surface of the backside gate contact includes a first inclined flat surface and a second inclined flat surface that are inclined with respect to the first direction, and
in a cross-sectional view in the second direction, the second contact surface of the frontside gate contact is a flat surface or a surface such that a middle portion of the second contact surface is at a lower vertical level than edge portions of the second contact surface.

19. The semiconductor device of claim 18, further comprising:
a lower source/drain pattern connected to the first lower channel pattern;
an upper source/drain pattern connected to the first upper channel pattern and spaced apart from the lower source/drain pattern in the first direction; and
an interlayer insulating film disposed between the lower source/drain pattern and the upper source/drain pattern.

20. The semiconductor device of claim 18, further comprising:
a channel isolation pattern disposed between the first lower channel pattern and the first upper channel pattern,
wherein the first gate structure surrounds the channel isolation pattern.
